(19) United States
(12) Patent Application Publication
(10) Pub. No.: US 2026/0260843 A1
(43) Pub. Date: Sep. 3, 2026

(54) SWITCH MATRIX CONFIGURATION FOR IMPROVED BANDWIDTH PERFORMANCE

(71) Applicant: ASML Netherlands B.V., Veldhoven (NL)

(72) Inventors: Jan BEX, Pelt (BE); Leonhard Martin KLEIN, Nueremberg (DE); Harald Gert Helmut NEUBAUER, Erlangen (DE); Matthias OBERST, Nürnberg (DE); Bernd Michael VOLLMER, Dresden (DE); Utku ULUDAG, Delft (NL); Hindrik Willem MOOK, The Hague (NL)

(73) Assignee: ASML Netherlands B.V., Veldhoven (NL)

(21) Appl. No.: 18/877,822

(22) PCT Filed: Jul. 27, 2023
(86) PCT No.: PCT/EP2023/070799

§ 371 Date: Dec. 20, 2024

(30) Foreign Application Priority Data
Aug. 11, 2022 (EP) 22189812.5

(51) Int. Cl. H01J 37/244; H03K 17/687

(52) U.S. Cl. CPC H01J 37/244; H03K 17/6871; H01J 2237/24495

(57) ABSTRACT

A charged particle detector includes a plurality of sensing elements. The sensing elements may be divided into in sections, with each section including an array of sensing elements. Each section may be coupled to adjacent sections by a set of switches in an upper hierarchy of a switch matrix. Individual sensing elements may be connected to the upper hierarchy in their section by pickup switches. Individual sensing elements may further be coupled to adjacent sensing elements by lateral switches in a lower hierarchy. When sensing elements are grouped together to detect a charged particle beam spot, an optimal configuration of lower and upper hierarchy switches may be selected to optimize bandwidth performance of the detector.

### CROSS-REFERENCE TO RELATED APPLICATIONS

This application claims priority of EP application 22189812.5 which was filed on Aug. 11, 2022 and which is incorporated herein in its entirety by reference.

### TECHNICAL FIELD

The description herein relates to detectors, and more particularly, to detectors that may be applicable to charged particle detection.

### BACKGROUND

Detectors may be used for sensing physically observable phenomena. For example, some charged particle beam tools, such as electron microscopes, comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided for this purpose. For example, a charged particle (e.g., electron) beam microscope, such as a scanning electron microscope (SEM) or a transmission electron microscope (TEM), capable of resolution down to less than a nanometer, serves as a practical tool for inspecting IC components having a feature size that is sub-100 nanometers. Electron microscopes work by irradiating a sample with an electron beam, then detecting secondary or backscattered electrons (or other types of secondary particles) on a detector. The secondary particles may form one or more beam spots on the detector surface.

Some detectors include a pixelated array of multiple sensing elements. A pixelated array can be useful because it may allow a detector configuration to be adapted to the size and shape of beam spots formed on the detector. When multiple primary beams are used, with multiple secondary beam spots incident on the detector, a pixelated array of sensing elements may be segregated into different groups associated with different beam spots. Sensing elements within a single group may have their detection signals merged with each other for readout by processing circuitry of the detector. The network of electronic switches used to group sensing elements together and merge their detection signals may be called a “switch matrix.”

### SUMMARY

Some embodiments of the present disclosure provide a method of configuring a switch matrix in a charged particle detector. The method may comprise: disabling a first inter-element switch between a first sensing element and a second sensing element of the charged particle detector to prevent charge from flowing between the first sensing element and the second sensing element via the first inter-element switch, the first inter-element switch forming part of a lower hierarchy of the switch matrix; enabling a first pickup switch between the first sensing element and an upper hierarchy of the switch matrix to allow charge to flow between the first sensing element and the upper hierarchy via the first pickup switch; and enabling a second pickup switch between the second sensing element and the upper hierarchy to allow charge to flow between the second sensing element and the upper hierarchy via the second pickup switch. The first sensing element and the second sensing element may be coupled to a common analog signal path of the detector at the upper hierarchy.

Some embodiments of the present disclosure provide a non-transitory computer-readable medium that stores a set of instructions that is executable by at least one processor of an apparatus to cause the apparatus to perform the above method.

Some embodiments of the present disclosure provide a charged particle beam apparatus configured to perform the above method. The charged particle beam apparatus ay comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface, wherein the charged particle detector comprises a first sensing element and a second sensing element; and a controller comprising one or more processors and configured to cause the charged particle beam apparatus to perform the above method.

Some embodiments of the present disclosure provide a further method of configuring a switch matrix in a charged particle detector. The further method may comprise: enabling a first pickup switch between a first sensing element and a first node of an upper hierarchy of the switch matrix to allow charge to flow between the first sensing element and the first node via the first pickup switch, the first sensing element receiving charged particles of a first beam spot; enabling a first inter-element switch between a second sensing element and a third sensing element to allow charge to flow between the second sensing element and the third sensing element via the first inter-element switch, the second sensing element and the third sensing element receiving charged particles of a second beam spot; disabling a second pickup switch between the second sensing element and the first node to prevent charge from flowing between the second sensing element and the first node via the pickup switch; and enabling a third pickup switch between the third sensing element and a second node of the upper hierarchy of the switch matrix to allow charge to flow between the third sensing element and the second node via the third pickup switch.

Some embodiments of the present disclosure provide a non-transitory computer-readable medium that stores a set of instructions that is executable by at least one processor of an apparatus to cause the apparatus to perform the above further method.

Some embodiments of the present disclosure provide a charged particle beam apparatus configured to perform the above method. The charged particle beam apparatus ay comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface, wherein the charged particle detector comprises a first sensing element and a second sensing element; and a controller comprising one or more processors and configured to cause the charged particle beam apparatus to perform the above further method.

Some embodiments of the present disclosure provide a charged particle detector having a switch matrix comprising an upper hierarchy and a lower hierarchy. The charged particle detector may comprise: a plurality of sections, each section comprising a plurality of sensing element circuits arranged in an array, each sensing element circuit comprising: a sensing element configured to generate charge from a charged particle landing event at the sensing element; a pickup switch configured to couple the sensing element to a node of the upper hierarchy of the switch matrix in the section; and an inter-element switch configured to couple the sensing element to an adjacent sensing element to allow charge to flow between the sensing element and the adjacent sensing element, the inter-element switch forming part of the lower hierarchy. Within each section of the plurality of sections, each sensing element may be configured to be coupled to a common node of the upper hierarchy in the section by its respective pickup switch.

Some embodiments of the present disclosure provide a charged particle beam apparatus. The charged particle beam apparatus may comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface, wherein the charged particle detector comprises a first sensing element and a second sensing element; a first inter-element switch that is configured to be disabled between the first sensing element and the second sensing element to prevent charge from flowing between the first sensing element and the second sensing element via the first inter-element switch, the first inter-element switch forming part of a lower hierarchy of a switch matrix; a first pickup switch that is configured to be enabled between the first sensing element and an upper hierarchy of the switch matrix to allow charge to flow between the first sensing element and the upper hierarchy via the first pickup switch; and a second pickup switch that is configured to be disabled between the second sensing element and the upper hierarchy to allow charge to flow between the second sensing element and the upper hierarchy via the second pickup switch. The first sensing element and the second sensing element may be coupled to a common analog signal path of the detector at the upper hierarchy.

Some embodiments of the present disclosure provide a charged particle beam apparatus. The charged particle beam apparatus may comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface, wherein the charged particle detector comprises a first sensing element, a second sensing element, and a third sensing element; a first pickup switch that is configured to be enabled between a first sensing element and a first node of an upper hierarchy of the switch matrix to allow charge to flow between the first sensing element and the first node via the first pickup switch, the first sensing element configured to receive charged particles of a first beam spot; a first inter-element switch that is configured to be enabled between a second sensing element and a third sensing element to allow charge to flow between the second sensing element and the third sensing element via the first inter-element switch, the second sensing element and the third sensing element configured to receive charged particles of a second beam spot; a second pickup switch that is configured to be disabled between the second sensing element and the first node to prevent charge from flowing between the second sensing element and the first node via the pickup switch; and a third pickup switch that is configured to be enabled between the third sensing element and a second node of the upper hierarchy of the switch matrix to allow charge to flow between the third sensing element and the second node via the third pickup switch.

### BRIEF DESCRIPTION OF DRAWINGS

FIG. 1 is a schematic diagram illustrating an exemplary charged-particle beam inspection system, consistent with embodiments of the present disclosure.

FIG. 2 is a schematic diagram illustrating an exemplary multi-beam beam tool, consistent with embodiments of the present disclosure that can be a part of the exemplary charged-particle beam inspection system of FIG. 1.

FIG. 3A is a schematic representation of an exemplary structure of a detector, consistent with embodiments of the present disclosure.

FIG. 3B is a diagram illustrating an exemplary surface of a detector array, consistent with embodiments of the present disclosure.

FIG. 4 is a diagram illustrating an exemplary detector array with switches, consistent with embodiments of the present disclosure.

FIG. 5 is a diagram illustrating a cross-sectional view of a layer structure of a detector, consistent with embodiments of the present disclosure.

FIG. 6 is a diagram illustrating a cross-sectional view of a sensing element of a detector, consistent with embodiments of the present disclosure.

FIG. 7 is a diagram representing an exemplary section arrangement of a detector, consistent with embodiments of the present disclosure.

FIG. 8 is a diagram representing a detection system, consistent with embodiments of the present disclosure.

FIGS. 9A-C are diagrams representing a detection system and switch matrix configuration according to a comparative embodiment.

FIGS. 10A-C are diagrams illustrating a detector array having an exemplary architecture, consistent with embodiments of the present disclosure.

FIG. 11 is a diagram illustrating beam spots on an exemplary detector surface, consistent with embodiments of the present disclosure.

FIG. 12 is a flowchart of an exemplary method of achieving a switching configuration, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing charged-particle beams (e.g., electron beams), the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Because the detector may need to capture a very large number of detection cycles in a very short time period, one of the critical factors in detector performance is its processing speed. One way to increase the processing speed is to maximize how fast the detector can transfer data. This data transfer rate is known as the bandwidth. Bandwidth can vary depending on the number and size of circuit components within the detector. Every component that is connected to the detector system will add unwanted electrical effects, known as parasitic parameters, that can slow the system down. Therefore, processing speed may be improved by minimizing the number of circuit components that are electrically connected to the system at any given time.

In addition to minimizing the total number of circuit components, it is also beneficial to design the structure of the components in a way that reduces their contribution to parasitic parameters. For instance, if it is possible to reduce the amount of current that is expected to pass through a circuit component, then that component may be made smaller to reduce its parasitic effects.

Speed is not the only concern in charged particle detectors. For some detectors, another important factor is adaptability. Because a single detector surface may detect multiple beam spots at the same time, the detector must be able to separate the signals it receives from each beam spot. To do this, the detector may be pixelated, such as by dividing the sensing surface into a grid of smaller sensing elements, where each sensing element corresponds to one pixel of the detector surface. The detector pixels can be connected to each other by a network of electronic switches known as a switch matrix. The switch matrix can link a first group of detection pixels to detect a first beam spot and can link a second group of detection pixels to detect a second beam spot. Signals from the two groups can be routed to a processor along different signal paths so that the beam spots are detected separately. Unused detection pixels between the two beam spots can be deactivated. While the pixelated detector is highly configurable, it also requires a high number of switches and other electronic components in the switch matrix, which can harm the bandwidth and processing speed.

Some embodiments of the present disclosure provide a pixelated electron detector architecture that achieves a high configurability with high bandwidth by using a hierarchical pixel switching array. Some embodiments of a hierarchical pixel switching array may comprise an array of detection pixels that may be selectively connected to each other by a switch matrix. The switch matrix may comprise an upper hierarchy layer having upper switches, a lower hierarchy layer having lower switches, and pickup switches in between the two hierarchy layers. Each sensing element may be coupled to adjacent sensing elements using the lower hierarchy switches. Each sensing element may be coupled to the upper hierarchy layer by a dedicated pickup switch. The upper hierarchy layer may be used to couple sections of switches to each other. Due to the flexibility of the switch matrix, a group of detector pixels may be coupled to each other by many different switching combinations. The optimal switching combination may be chosen to maximize bandwidth and processing speed. Any switches that are not needed may be deactivated to reduce parasitic parameters.

Relative dimensions of components in drawings may be exaggerated for clarity. Within the following description of drawings, the same or like reference numbers refer to the same or like components or entities, and only the differences with respect to the individual embodiments are described.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, or the like.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

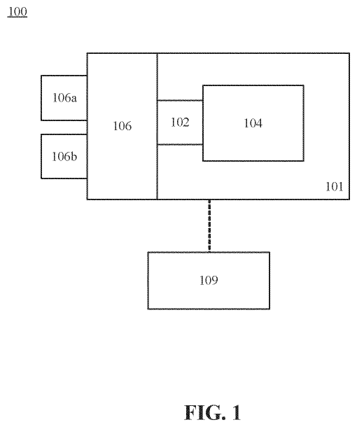

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front disabling unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

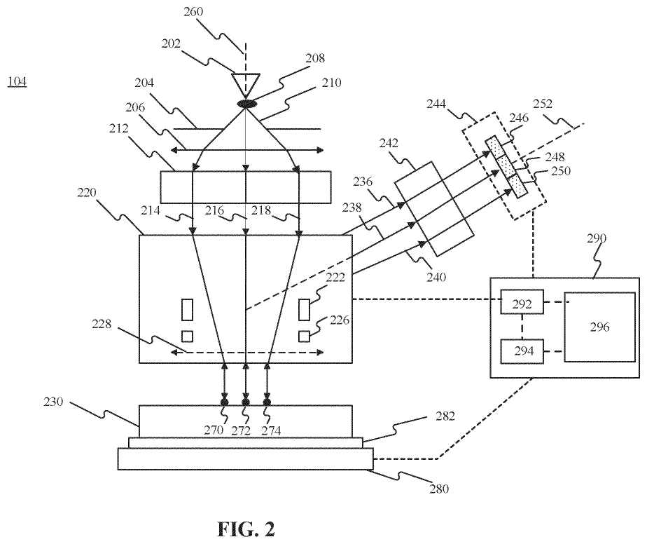

FIG. 2 illustrates a schematic diagram of an exemplary multi-beam beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

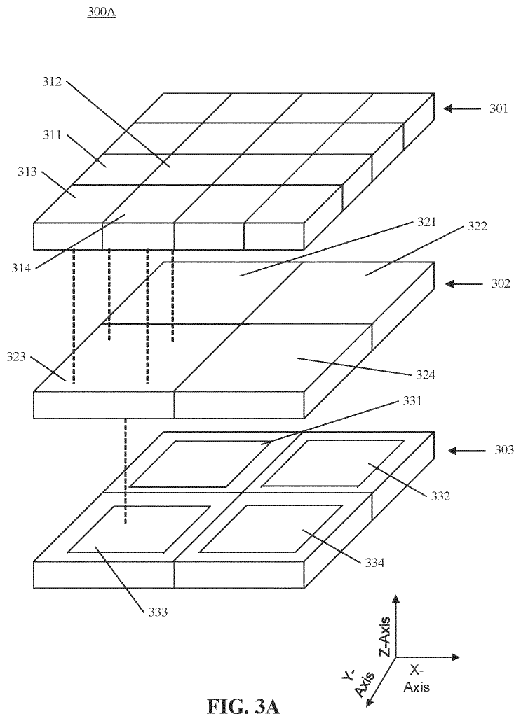

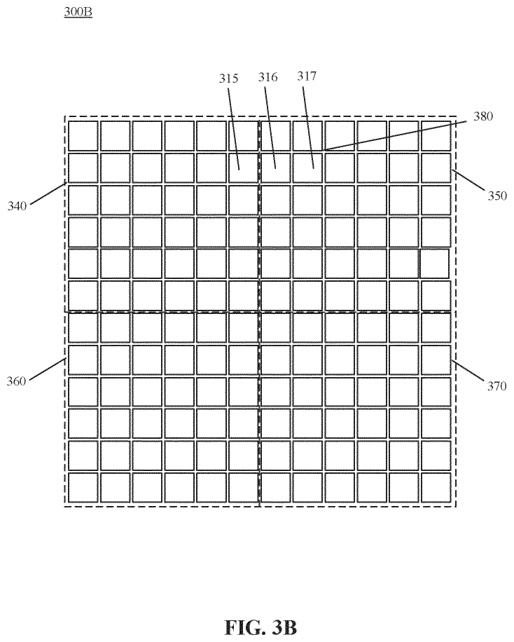

FIG. 3A illustrates a schematic representation of an exemplary structure of a detector 300A, consistent with embodiments of the present disclosure. Detector 300A may be provided as charged-particle detection device 244. In FIG. 3A, detector 300A includes a sensor layer 301, a section layer 302, and a readout layer 303. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement. Detector 300A may have an arrangement with respect to a coordinate axis reference frame. Sensor layer 301 may be arranged along an x-y plane. Sensing elements in sensor layer 301 may be arrayed in x-axis and y-axis directions. The x-axis direction may also herein be referred to as a “horizontal” direction. The y-axis direction may also herein be referred to as a “vertical” direction. Detector 300A may have a layer structure in which sensor layer 301, section layer 302, and section layer are stacked in a z-axis direction. The z-axis direction may also herein be referred to as a “thickness” direction. The z-axis direction may be aligned with a direction of incidence of charged particles that are directed toward detector 300A.

Section layer 302 may include multiple sections, including sections 321, 322, 323, and 324. The sections may include interconnections (e.g., wiring paths) configured to communicatively couple the multiple sensing elements. The sections may also include switches that may control the communicative couplings between the sensing elements. The sections may further include connection mechanisms (e.g., wiring paths and switches) between the sensing elements and one or more common nodes in the section layer. For example, as shown in FIG. 3A, section 323 may be configured to communicatively couple to outputs of sensing elements 311, 312, 313, and 314, as shown by the four dashed lines between sensor layer 301 and section layer 302. In some embodiments, section 323 may be configured to output combined signals gathered from sensing elements 311, 312, 313, and 314 as a common output. In some embodiments, a section (e.g., section 323) may be communicatively coupled to sensing elements (e.g., sensing elements 311, 312, 313, and 314) placed directly above the section. For example, section 323 may have a grid of terminals configured to connect with the outputs of sensing elements 311, 312, 313, and 314. In some embodiments, sections 321, 322, 323, and 324 may be provided in an array structure such that they have a uniform size and shape, and a uniform arrangement. Sections 321, 322, 323, and 324 may be square shaped, for instance. In some embodiments, an isolation area may be provided between adjacent sections to electrically insulate them from one another. In some embodiments, sections may be arranged in an offset pattern, such as a tile layout.

Readout layer 303 may include signal processing circuits for processing outputs of the sensing elements. In some embodiments, signal processing circuits may be provided, which may correspond with each of the sections of section layer 302. In some embodiments, multiple separate signal processing circuitry sections may be provided, including signal processing circuitry sections 331, 332, 333, and 334. In some embodiments, the signal processing circuitry sections may be provided in an array of sections having a uniform size and shape, and a uniform arrangement. In some embodiments, the signal processing circuitry sections may be configured to connect with an output from corresponding sections of section layer 302. For example, as shown in FIG. 3A, signal processing circuitry section 333 may be configured to communicatively couple to an output of section 323, as shown by the dashed line between section layer 302 and readout layer 303.

In some embodiments, readout layer 303 may include input and output terminals. Output(s) of readout layer 303 may be connected to a component for reading and interpreting the output of detector 300A. For example, readout layer 303 may be directly connected to a digital multiplexer, digital logic block, controller, computer, or the like.

The sizes of sections and the number of sensing elements associated with a section may be varied. For example, while FIG. 3A illustrates a 2×2 array of four sensing elements in one section, embodiments of the disclosure are not so limited. A section may comprise an array of, e.g., 3×3, 4×4, 1×6, or any desired number of sensing elements.

While FIG. 3A illustrates sensor layer 301, section layer 302, and readout layer 303 as multiple discrete layers, it is noted that sensor layer 301, section layer 302, and readout layer 303 need not be provided as separate substrates. For example, a wiring path of section layer 302 may be provided in a sensor die including the multiple sensing elements, or may be provided outside of the sensor die. Wiring paths may be patterned on sensor layer 301. Additionally, section layer 302 may be combined with readout layer 303. For example, a semiconductor die may be provided that includes wiring paths of section layer 302 and signal processing circuits of readout layer 303. Thus, structures and functionalities of the various layers may be combined or divided.

In some embodiments, a detector may be provided in a two-die configuration. However, embodiments of the present disclosure are not so limited. For example, functions of a sensor layer, section layer, and readout layer may be implemented in one die or in a package that may contain one or more dies.

In some embodiments, arrangements of sensor layer 301, section layer 302, and readout layer 303 may correspond with one another in a stacked relationship. For example, section layer 302 may be mounted directly on top of readout layer 303, and sensor layer 301 may be mounted directly on top of section layer 302. The layers may be stacked such that sections within section layer 302 are aligned with signal processing circuitry sections (e.g., sections 331, 332, 333, and 334) of readout layer 303. Furthermore, the layers may be stacked such that one or more sensing elements within sensor layer 301 are aligned with a section in section layer 302. In some embodiments, sensing elements to be associated with a section may be contained within the section. For example, in a plan view of detector 300A, sensing elements (e.g., sensing elements 311, 312, 313, and 314) of a section (e.g., section 323) may fit within the boundaries of the section. Furthermore, individual sections of section layer 302 may overlap with signal processing circuitry sections of readout layer 303. In this manner, predefined areas may be established for associating sensing elements with sections and signal processing circuitry.

FIG. 3B illustrates an exemplary structure of a sensor surface 300B that may form a surface of charged-particle detection device 244, consistent with embodiments of the present disclosure. Sensor surface 300B may be provided with multiple sections of sensing elements, including sections 340, 350, 360, and 370, which are represented by the dashed lines. For example, sensor surface 300B may be the surface of sensor layer 301 in FIG. 3A. Each section may be capable of receiving at least a part of a beam spot emitted from a particular location from wafer 230, such as one of secondary charged-particle beams 236, 238, and 240 as shown in FIG. 2.

Sensor surface 300B may include an array of sensing elements, including sensing elements 315, 316, and 317. In some embodiments, each of sections 340, 350, 360, and 370 may contain one or more sensing elements. For example, section 340 may contain a first plurality of sensing elements, and section 350 may contain a second plurality of sensing elements, and so on. The first plurality of sensing elements and the second plurality of sensing elements may be mutually exclusive. In some embodiments, a sensing element may be a diode or any element similar to a diode that can convert incident energy into a measurable signal. For example, the sensing elements may include a PIN diode, an avalanche diode, an electron multiplier tube (EMT), or other components.

In FIG. 3B, an area 380 may be provided between adjacent sensing elements. Area 380 may be an isolation area to isolate the sides or corners of neighboring sensing elements from one another. In some embodiments, area 380 may include an insulating material that is different from that of the sensing elements of sensor surface 300B. In some embodiments, area 380 may be provided as a square. In some embodiments, area 380 may not be provided between adjacent sides of sensing elements.

In some embodiments, a field programmable detector array may be provided with sensing elements having switching regions integrated between the sensing elements. For example, detectors may be provided such as some of those examples discussed in PCT Application No. PCT/EP2018/074833, filed on Sep. 14, 2018, the content of which is herein incorporated by reference in its entirety. In some embodiments, a switching region may be provided between sensing elements so that some or more of the sensing elements may be grouped when covered by the same charged-particle beam spot. Circuits for controlling the switching regions may be included in the signal processing circuits of the readout layer (e.g., readout layer 303 in FIG. 3A). As used throughout the present disclosure, the expression “a set of sensing elements” shall mean a group of sensing elements of a first quantity. A first set of sensing elements among the set of sensing elements may refer to a subset of sensing elements within the set. A second set of sensing elements may refer to another subset of sensing elements within the set. The first and second sets may or may not be mutually exclusive. A “group” of sensing elements may refer to sensing elements that are associated with one beam spot projected on a detector surface (e.g., within the boundary of the beam spot). First and second sets of sensing elements may refer to different groups of sensing elements that are associated with different beam spots. The sets of sensing elements need not be restricted to particular “sections” of a detector.

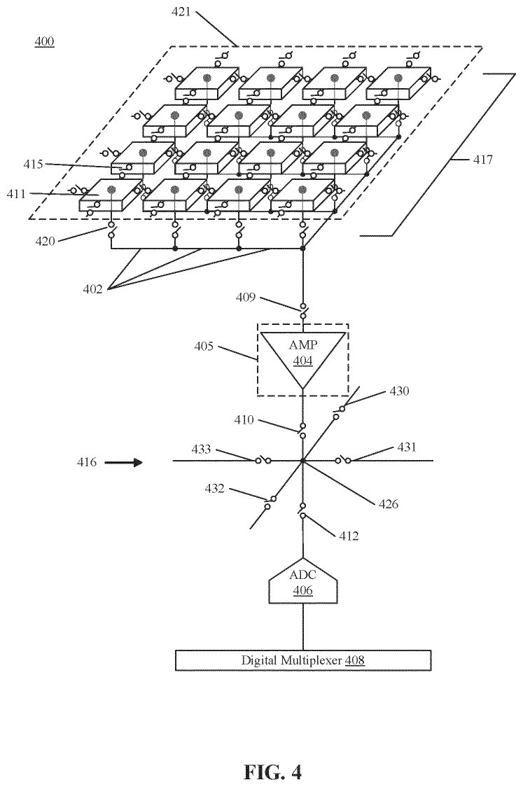

FIG. 4 is a diagram illustrating an exemplary detector array 400 with switches, consistent with embodiments of the present disclosure. The architecture of FIG. 4 may be used in either a single-beam inspection tool or a multibeam inspection tool (e.g., beam tool 104 in FIG. 2). Detector array 400 may be an example embodiment of detector 300A in FIG. 3A. The 4×4 array of section 421 may have a similar architecture to the 2×2 arrays in any of sections 321-324 of FIG. 3A. For example, detector array 400 may include a sensor layer (e.g., similar to sensor layer 301 in FIG. 3A), a section layer (e.g., similar to section layer 302 in FIG. 3A), and a readout layer (e.g., similar to readout layer 303 in FIG. 3A). The sensor layer of detector array 400 may include multiple sensing elements, including sensing elements 411. In some embodiments, each of the sensing elements of detector array 400 may have a uniform size, shape, and arrangement. The sensing elements of detector array 400 may generate an electric current signal commensurate with the charged particles (e.g., exiting electrons) received in the active areas of the sensing elements. The “active areas” herein may refer to areas of the sensing elements having radiation sensitivity above a predetermined threshold value.

The section layer of detector array 400 may include a base substrate (e.g., a semiconductor substrate, not shown in FIG. 4) including one or more wiring paths 402. Wiring paths 402 may be configured to communicatively couple the sensing elements of detector array 400. As shown in FIG. 4, detector array 400 includes a section 421 having a 4×4 array of sensing elements 411.

In FIG. 4, the section layer of detector array 400 may include inter-element switches 415 between any two adjacent sensing elements. Sections of detector array 400, such as section 421 in FIG. 4 (or sections 321-324 in FIG. 3A or sections 340-370 in FIG. 3B), may be coupled to each other by inter-element switches 415 communicatively coupled to edges of the sections. This lateral network of inter-element switches 415 may form part of a “lower hierarchy” layer of the switch matrix.

Wiring paths 402 may be configured to communicatively couple to outputs of sensing elements 411 in section 421. For example, wiring paths 402 may have a grid of terminals (shown as round black dots at the centers of the sensing elements) configured to connect with the outputs of sensing elements 411. In some embodiments, wiring paths 402 may be provided in the section layer of detector array 400. In FIG. 4, wiring paths 402 are communicatively coupled to the sensing elements 411 above them. In FIG. 4, element-bus switches 420 may be provided between the outputs of the sensing elements and wiring paths 402. In some embodiments, the element-bus switches 420 may be provided in the section layer of detector array 400.

In some embodiments, wiring paths 402 may include lines of conductive material printed on the base substrate, flexible wires, bonding wires, or the like. In some embodiments, switches may be provided so that outputs of individual sensing elements can be connected or disconnected with the common output of section 421. In some embodiments, the section layer of detector array 400 may further include corresponding circuits for controlling the switches. In some embodiments, switches may be provided in a separate switch-element matrix that may itself contain circuits for controlling the switches.

The readout layer of detector array 400 may include signal conditioning circuits for processing outputs of the sensing elements. In some embodiments, the signal conditioning circuits may convert the generated current signal into a voltage that may represent the intensity of a received beam spot or may amplify the generated current signal into an amplified current signal. The signal conditioning circuit may include, for example, an amplifier 404 and one or more analog switches. The amplifier 404 may be a high speed transimpedance amplifier, a current amplifier, or the like. In FIG. 4, amplifier 404 may be communicatively coupled to the common output of section 421 for amplifying the output signals of the sensing elements of section 421. In some embodiments, amplifier 404 may be a single-stage or a multi-stage amplifier. For example, if amplifier 404 is a multi-stage amplifier, it may include a pre-amplifier and a post-amplifier, or include a front-end stage and a post stage, or the like. In some embodiments, amplifier 404 may be a variable gain amplifier, such as a variable gain transimpedance amplifier (VGTIA), a variable gain charge transfer amplifier (VGCTA), or the like. The conditioning circuit may be coupled to a signal path that may include, for example, an analog-to-digital converter (ADC) 406. In FIG. 4, ADC 406 may be communicatively coupled to the output of the conditioning circuit (e.g., including amplifier 404) to convert the analog output signals of the sensing elements of section 421 to digital signals. The readout layer of detector array 400 may also include other circuits for other functions. For example, the readout layer of detector array 400 may include switch-element actuating circuits that may control the switches between the sensing elements. For ease of explanation without causing ambiguity, the signal path between the sensing elements and ADC 406 may be referred to as an “analog signal path.” For example, the analog signal path in FIG. 4 includes the above-described signal conditioning circuit (e.g., including amplifier 404). The input of the analog signal path is communicatively coupled to the sensing elements, and the output of the analog signal path is communicatively coupled to ADC 406. The signal path between the sensing elements and a readout layer may be referred to as a “signal readout path,” and may be the same as, or different than, the analog signal path. For example, the signal readout path may include the analog signal path, or multiple analog signal paths, and may extend further into a readout layer of the detector 400, such as to a digital multiplexer 408.

In some embodiments, ADC 406 may include output terminals communicatively coupled to a component (e.g., a component inside or outside the readout layer of detector array 400) for reading and interpreting the digital signal converted by ADC 406. In FIG. 4, ADC 406 is communicatively coupled to digital multiplexer 408. In some embodiments, digital multiplexer 408 may be arranged in the readout layer of detector array 400. Digital multiplexer 408 may receive multiple input signals and convert them as an output signal. The output signal of digital multiplexer 408 may be converted back to the multiple input signals. The output signal of digital multiplexer 408 may be further transmitted to a data processing stage (e.g., image processing system 290 in FIG. 2).

In some embodiments of the present disclosure, detector 400 may include a further layer of switches, such as interconnection layer 416 that communicatively couples outputs of signal processing circuitry to each other. The signal processing circuitry may include analog signal paths. As used within the present specification and appended claims, the act of closing a switch (or of maintaining the switch in a closed state) so as to allow charge to flow through the switch, may be referred to as “enabling” the switch. Similarly, the act of disabling a switch (or of maintaining the switch in an opened state) so as to prevent charge from flowing through the switch, may be referred to as “disabling” the switch.

As shown in FIG. 4, interconnection layer 416 includes interconnection switches communicatively coupled to outputs of analog signal paths of detector array 400. For example, interconnection switches 430-433 may communicatively couple the outputs of adjacent analog signal paths from neighboring sections of sensing elements 411. Detector array 400 includes an analog signal path 405 associated with section 421, which starts from the output of section 421 and ends at the input of an interconnection layer 416.

The interconnection switches 430-433 within interconnection layer 416 may form part of an “upper hierarchy” layer of the switch matrix. Interconnection switches may form a repeating unit cell that corresponds to each section of sensing elements. For example, interconnection switches 430 and 431 may form a repeating unit cell in the interconnection layer 416 that corresponds to section 421. In the orientation of FIG. 4, interconnection switch 430 may form a top switch that couples section 421 to another section of sensing elements (not shown) “above” it in the plane of detector 400, while interconnection switch 431 may form a right switch that couples section 421 to another section of sensing elements to the right in the plane (also not shown). Similarly, interconnection switch 433 may constitute a right switch from the section to the left of section 421, while interconnection switch 432 may constitute a top switch from the section below section 421 in the plane of detector 400. As each interconnection switch is actually shared by two adjacent sections rather than belonging to one section in particular, the naming scheme is arbitrary. Each element-bus switch 420 may connect its respective sensing element 411 to the interconnection layer 416, along with any other sensing elements that have been connected to the respective sensing element via inter-element switches 415. Thus, element bus switches 420 may serve as connections between the network of inter-element switches 415 in the lower hierarchy and the network of interconnection switches 430-433 in the upper hierarchy.

In FIG. 4, a switch 409 may communicatively couple an output of section 421 to an input of analog signal path 405, and switch 410 may communicatively couple an output of analog signal path 405 to an input (e.g., input/output point 426 or “I/O point” 426) of interconnection layer 416. Switches 409 and 410 may be configured to be communicatively disconnected if analog signal path 405 is not selected for use. For example, a charged-particle beam may impinge on some or all of the sensing elements of section 421, but the detection signals of section 421 may be redirected to another analog signal path corresponding to another section of detector array 400, as further discussed below. In such a case, analog signal path 405 may be disconnected as a result of not being selected. In some embodiments, if no sensing element of section 421 is impinged by any charged-particle and analog signal path 405 is not selected for use (e.g., to process signal from other sections), besides communicatively disconnecting switches 409 and 410, amplifier 404 may also be disabled to reduce power consumption. When switches 409 and 410 are communicatively disconnected, analog signal path 405 (including amplifier 404) may be effectively deactivated from detector array 400.

The switch matrix comprising, e.g., inter-element switches 415, element-bus switches 420, and interconnection switches 430-433 may be configured to route signals from sensing elements to the readout layer of detector array 400 by a variety of signal readout paths. For example, when only one beam spot is incident on section 421, sensing elements may be directly coupled to the readout layer via element bus switches 420 and switches 409-410. For instance, if a beam spot has been determined previously (such as during a “picture mode” discussed below) to be incident on all sensing elements in section 421, then the entire section may be coupled to the signal readout path via element-bus switches at each sensing element in section 421. Inter-element switches 415 between the sensing elements in section 421 may be left open to reduce parasitic parameters such as series resistance and parasitic capacitance. If, for example, sensing element 411 in FIG. 4 is determined to be receiving a portion of a beam spot and the remaining sensing elements of section 421 are not, then only that sensing element may be connected by enabling its element-bus switch 420, while the remaining sensing elements are disconnected by leaving their own element-bus switches open.

At the same time, neighboring sensing elements from neighboring sections may be coupled to a common signal readout path with section 421 at interconnection layer 416. For example, if a beam spot is incident on section 421 as well as on an adjacent section to the left of section 421 (not shown in FIG. 4), then the neighboring sensing elements from the adjacent section may be coupled to interconnection layer 416 by their respective element-bus switches 420, and the sensing elements 411 of section 421 may do the same by their own element-bus switches 420 (as well as any intervening switches, such as input/output switches 409/410 at amplifier 404). The two sections may be coupled to a common analog signal path, e.g., by enabling interconnection switch 433 and ADC switch 412.

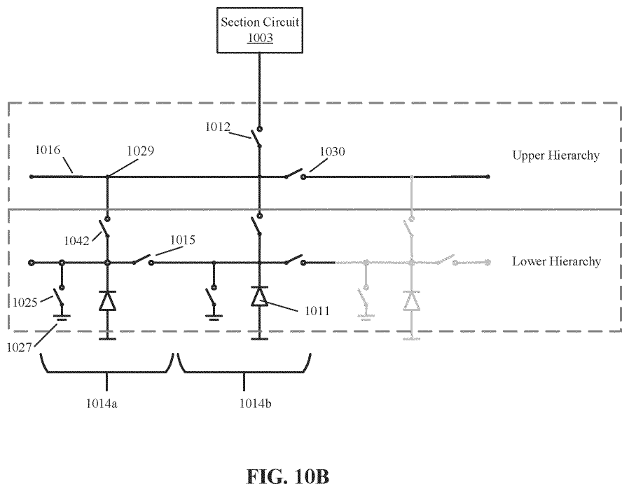

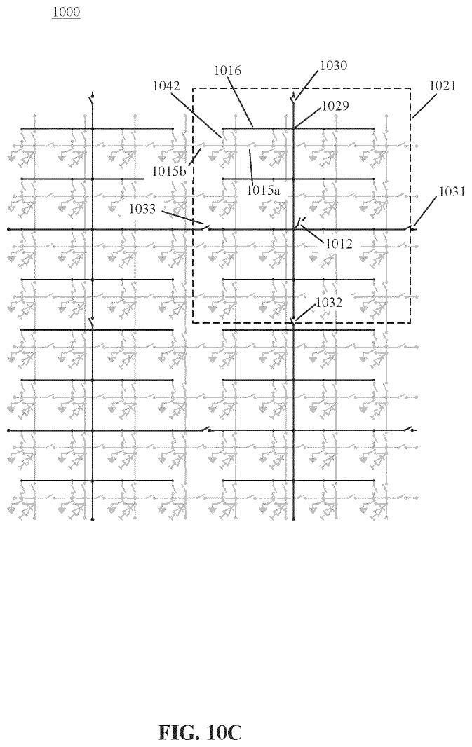

Alternatively, neighboring sensing elements from the adjacent section may be coupled to section 421 by enabling inter-element switches 415 between outer sensing elements 411 of section 421 and the neighboring sensing elements from the adjacent section. This is illustrated further below, e.g., with respect to FIG. 10C. In such a case, because signals from the neighboring sensing elements are routed along the inter-element switches of the lower hierarchy layer, element bus switches 420 of the adjacent section may be opened to reduce parasitic parameters. Interconnection switch 433 may also be open. Signals from both section 421 and the adjacent section may be routed to ADC 406 by element bus switches 420, wiring paths 402, analog signal path 405 and I/O point 426.

Another situation occurs when two different beam spots are incident on two different portions of a single section of sensing elements, such as section 421. In this case, signals from the two beam spots must be routed along different signal readout paths in order to differentiate them. It may not be possible to differentiate the signals if both portions are coupled to analog signal path 405. For example, a first beam spot may be incident on the sensing element actually labeled 411, as well as on the adjacent section to the left of section 421 discussed above. A second beam spot may be incident on the entire row 417 of sensing elements along the right-hand side, as well as a further adjacent section to the right of section 421 in FIG. 4 (not shown). If both sets of sensing elements in section 421 are routed through analog signal path 405, their signals would not be differentiable. Therefore at least one of the portions may be connected to the adjacent section with which it shares a common beam spot.

For instance, sensing element 411 may be connected to the adjacent section on the left side of section 421 by the inter-element switches on their left sides in FIG. 4. The neighboring section to the left may then be routed along an analog signal path other than analog signal path 405 of FIG. 4. Furthermore, interconnection switch 433 may be open to disconnect the adjacent section from a signal readout path comprising analog signal path 405, and the element-bus switch 420 below the sensing element actually labeled 411 may be open as well. At the same time, row 417 may be coupled to analog signal path 405 via the element-bus switches 420 corresponding to each sensing element 411 within row 417. Analog signal path 405 may be connected to an analog signal path of the adjacent section to the right by, e.g., enabling interconnection switch 431. Thus, row 417 may be coupled to its adjacent section on the right without enabling the inter-element switches 415 to the right of row 417.

The decision to route the two portions in the exemplary manner discussed above may be determined based on, e.g., a desire to minimize parasitic parameters in the system. For example, if parallel paths along element-bus switches 420 are preferred over series paths along inter-element switches 415, the routing may be determined such that fewer inter-element switches 415 are connected to the system. In general, a total measure of parasitic parameters may be considered when determining optimal signal readout paths.

Further details of detector array 400 may be found in U.S. Provisional Patent Application No. 63/019,179, which is incorporated herein by reference in its entirety.

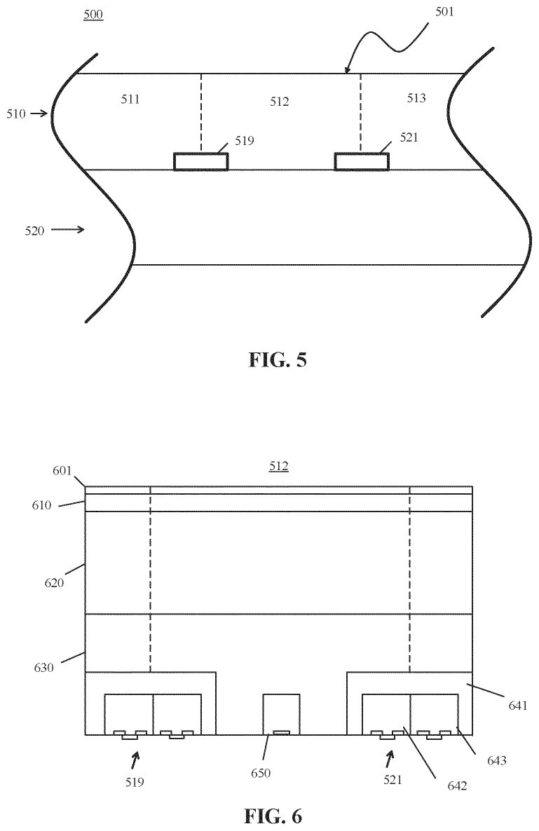

FIG. 5 is a diagram illustrating a cross-sectional view of a layer structure of a detector 500, consistent with embodiments of the present disclosure. Detector 500 may be provided as charged-particle detection device 244 in a charged-particle beam tool 104 as shown in FIG. 2. Detector 500 may be configured to have multiple layers stacked in a thickness direction, the thickness direction being substantially parallel to an incidence direction of a charged-particle beam. In some embodiments, detector 500 may be provided such as some of those examples discussed in PCT Application No. PCT/EP2018/074834, filed on Sep. 14, 2018, the content of which is herein incorporated by reference in its entirety.

In FIG. 5, detector 500 may include a sensor layer 510 and a circuit layer 520. In some embodiments, sensor layer 510 may represent sensor layer 301 in FIG. 3A, and circuit layer 520 may represent section layer 302 and readout layer 303 in FIG. 3A. For example, circuit layer 520 may include interconnects (e.g., metal lines), and various electronic circuit components. As another example, circuit layer 520 may include a processing system. Circuit layer 520 may also be configured to receive the output current detected in sensor layer 510. In some embodiments, sensor layer 510 may represent sensor layer 301 and section layer 302 in FIG. 3A, and circuit layer 520 may represent readout layer 303 in FIG. 3A. In some embodiments, detector 500 may include layers in addition to sensor layer 301, section layer 302, and readout layer 303.

In some embodiments, sensor layer 510 may be provided with a sensor surface 501 for receiving incident charged particles. Sensing elements, including sensing elements 511, 512, and 513 (differentiated by dashed lines), may be provided in sensor layer 510. For example, sensor surface 501 may be similar to sensor surface 300B in FIG. 3B. In FIG. 5, switches, including switches 519 and 521, may be provided between adjacent sensing elements in a horizontal direction in the cross-sectional view. Switches 519 and 521 may be embedded in sensor layer 510. In some embodiments, sensing elements 511, 512, and 513 may be among the sensing elements 411 of detector 400 in FIG. 4, and switches 519 and 521 may be among the switches 415 between the sensing elements of detector array 400 in FIG. 4.

In some embodiments, sensing elements 511, 512, and 513 may be separated by an isolation area (indicated by the dashed lines) extending in the thickness direction. For example, sides of sensing elements 511, 512, and 513 that are parallel to the thickness direction may be isolated from each other by the isolation areas (e.g., area 380 in FIG. 3B).

In some embodiments, sensor layer 510 may be configured as one or more diodes where sensing elements 511, 512, and 513 are similar to sensing elements 315, 316, and 317 of FIG. 3B. Switches 519 and 521 may be configured as transistors (e.g., MOSFETs). Each of sensing elements 511, 512, 513 may include outputs for making electrical connections to circuit layer 520. For example, the outputs may be integrated with switches 519 and 521, or may be provided separately. In some embodiments, the outputs may be integrated in a bottom layer of sensor layer 510 (e.g., a metal layer).

Although FIG. 5 depicts sensing elements 511, 512, and 513 as discrete units when viewed in cross-section, such divisions may not actually be physical. For example, the sensing elements of detector 500 may be formed by a semiconductor device constituting a PIN diode device that can be manufactured as a substrate with multiple layers including a P-type region, an intrinsic region, and an N-type region. In such an example, sensing elements 511, 512, 513 may be contiguous in cross-sectional view. In some embodiments, the switches (e.g., switches 519 and 521) may be integrated with the sensing elements.

In some embodiments, switches may be integrated within the sensor layer, integrated within other layers, or may be provided partially or fully in existing layers. In some embodiments, for example, the sensor layer may contain wells, trenches, or other structures, wherein the switches are formed in those structures.

In some embodiments, the switches (e.g., switches 519 and 521) of detector 500 may be provided outside of sensor layer 510. For example, the switches may be embedded in circuit layer 520 (not shown in FIG. 5). In some embodiments, the switches (e.g., switches 519 and 521) of detector 500 may be formed in a separate die (e.g., a switch die). For example, the switch die (not shown in FIG. 5) may be sandwiched between and be communicatively connected to sensor layer 510 and circuit layer 520.

FIG. 6 is a diagram illustrating a cross-sectional view of sensing element 512 of detector 500, consistent with embodiments of the present disclosure. In FIG. 6, sensing element 512 may include a P-well and an N-well for forming switches and other active or passive elements that may be communicatively coupled to other components of sensor layer 510 or circuit layer 520. Although FIG. 6 only shows one full sensing element 512, it is understood that sensor layer 510 may be made up of multiple sensing elements similar to sensing element 512 (e.g., sensing elements 511 and 513), which may be contiguous in cross-sectional view.

In some embodiments, sensing element 512 may include a diode device having a surface layer 601, a P-type region 610, a P-epitaxial region 620, an N-type region 630, and other components. Surface layer 601 may form a detection surface (e.g., an active area) of a detector that receives incident charged particles. For example, surface layer 601 may be a metal layer (e.g., formed by aluminum or other conductive materials). On an opposite side from surface layer 601, there may be provided an electrode 650 as a charge collector. Electrode 650 may be configured to output a current signal representing the number of charged particles received in the active area of sensing element 512.

In some embodiments, as shown in FIG. 6, switches 519 and 521 may be formed by metal oxide semiconductor (MOS) devices. For example, multiple MOS devices may be formed in a back side of N-type region 630 in FIG. 6, and the back side of N-type region 630 may be in contact with sensor layer 510 in FIG. 5. As an example of a MOS device, there may be provided a deep P-well 641, an N-well 642, and a P-well 643. In some embodiments, the MOS devices may be fabricated by etching, patterning, and other processes and techniques. It will be understood that various other devices may be used, such as bipolar semiconductor devices, etc., and devices may be fabricated by various processes.

In operation of sensing element 512, when charged particles (e.g., secondary charged-particle beams 236, 238, and 240 in FIG. 2) impinge on surface layer 601, the body of sensing element 512, including, e.g., a depletion region, may be flooded with charge carriers generated from the impinged charged particles. Such a depletion region may extend through at least a portion of the volume of the sensing element. For example, the charged particles may be electrons, and the impinged electrons may create and energize electron-hole pairs in a depletion region of the sensing element. The energized electrons among the electron-hole pairs may have further energy such that they may also generate new electron-hole pairs. Electrons generated from the impinged charged particles may contribute to signal generated in each sensing element.

With reference to FIG. 6, a depletion region in sensing element 512 may include an electric field between P-type region 610 and N-type region 630, and the electrons and the holes may be attracted by P-type region 610 and N-type region 630, respectively. When the electrons reach P-type region 610 or when the holes reach N-type region 630, a detection signal may be generated. Thus, sensing element 512 may generate an output signal, such as current, when a charged particle beam is incident on sensing element 512. Multiple sensing elements may be connected, and a group of sensing elements may be used to detect intensity of a charged particle beam spot. When a charged particle beam spot covers multiple adjacent sensing elements (e.g., sensing elements 511, 512, and 513), the sensing elements may be grouped together (“merged”) for collecting current. For example, the sensing elements may be merged by turning on switches (e.g., switches 519 and 521) between them. Signals from sensing elements in a group may be collected and sent to a signal conditioning circuit connected to the group. The number of sensing elements in a group may be an arbitrary number related to the size and shape of the beam spot. The number may be 1 or greater than 1.

In some embodiments, a detector may be configured so that individual sensing elements may communicate with external components via, for example, signal or data lines and address signals. A detector may be configured to actuate switches so that two or more sensing elements may be merged, and their output current or voltage may be combined. As can be seen in FIGS. 5-6, with the switch-element design between the sensing elements, the sensing elements may be provided without physical isolation areas (e.g., area 380 in FIG. 3B). Thus, when sensing element 512 is activated, all of the area under surface layer 601 may become active. When no physical isolation area is provided between adjacent sensing elements, dead area between them may be minimized or eliminated.

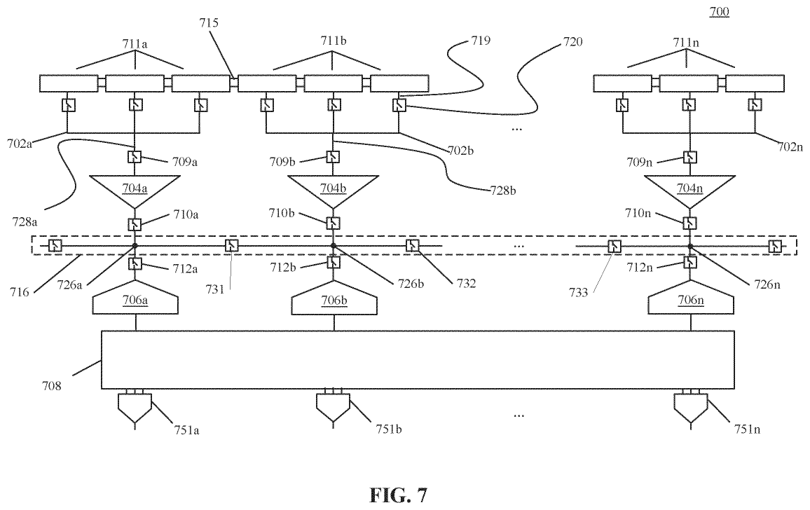

FIG. 7 is a diagram representing an exemplary section arrangement of a detector 700, consistent with embodiments of the present disclosure. For example, detector 700 may be an embodiment of detector 300A in FIG. 3A, detector array 400 in FIG. 4, or detector 500 in FIG. 5. As shown in FIG. 7, detector 700 may include multiple sensing elements, including sensing elements 711, such as sensing elements 711a-711n. In some embodiments, the multiple sensing elements may be part of a sensor layer that may form a detection surface (e.g., sensor surface 300B in FIG. 3B) of charged-particle detection device 244 in FIG. 2. The sensor layer may include switches between adjacent sensing elements (e.g., similar to switches 519 and 521 in FIG. 6), including inter-element switches 715. In some embodiments, when being turned on, the switches may be configured to group two or more adjacent sensing elements together.

In FIG. 7, detector 700 may include multiple sections (e.g., similar to sections 321, 322, 323, and 324 in FIG. 3A). Each of the sections may include one or more sensing elements, and wiring paths (e.g., similar to wiring paths 402 in FIG. 4) between the sensing elements, and a common output. In some embodiments, the wiring paths may include a common wire or a shared signal path. For example, as shown in FIG. 7, wiring paths 702a may be communicatively connected to sensing elements 711a, and to a common output 728a. Wiring paths 702a, sensing elements 711a, and common output 728a may belong to a first section. Wiring paths 702b may be communicatively connected to sensing elements 711b, and to a common output 728b. Wiring paths 702b, sensing elements 711b, and common output 728b may belong to a second section. In general a detector may have some arbitrary number of sections (represented by “n” in FIG. 7) where corresponding components share the same numerals and differing letters. When referring generally to all such components, the letter may be omitted (e.g., “sensing element 711” may refer to sensing elements 711a, sensing elements 711b, sensing elements 711n, etc.). An output (e.g., output 719) of a sensing element (e.g., right-most sensing element 711b) may be communicatively coupled to corresponding wiring paths (e.g., wiring paths 702b) via an element-bus switch (e.g., element-bus switch 720). In some embodiments, element-bus switch 720 may be implemented using techniques similar to switches 519 and 521 as described in FIG. 6. In some embodiments, when the sensing element 711b is inactive, element-bus switch 720 may be disconnected to reduce noise, parasitic capacitance, or other technical effects from the sensing element and related circuitry.

In FIG. 7, the sections (e.g., the first section including sensing elements 711a or the second section including sensing elements 711b) may be configured to output electrical signals to signal processing circuits and further circuit elements. For example, wiring paths 702 may output electrical signals to signal processing circuitry 704-706 via common outputs 728.

Signal processing circuitry may include one or more signal processing circuits for processing electrical signals output by wiring paths 728. For example, signal processing circuitry 704-706 may include an amplifier 704 (comprising, e.g. a pre-amplifier and a post-amplifier), and a data converter 706. Examples of a pre-amplifier include a transimpedance amplifier (TIA), a charge transfer amplifier (CTA), a current amplifier, or the like. Examples of a post-amplifier include a variable gain amplifier (VGA) or the like. Data converter 706 may be an analog-to-digital converter (ADC), which may convert an analog voltage or an analog current to a digital value. In some embodiments, the pre- and post-amplifiers may be combined as a single amplifier 706 (e.g., amplifier 404 in FIG. 4), and data converter 706 may include ADC 406 in FIG. 4.

Detector 700 may include a digital switch 708. In some embodiments, digital switch 708 may include a switch-element matrix. In some embodiments, digital switch 708 may include a multiplexer (e.g., digital multiplexer 408 in FIG. 4). For example, the multiplexer may be configured to receive a first number of inputs and generate a second number of outputs, in which the first number and the second number may be the same or different. The first number may correspond to parameters (e.g., a total number of sections) of detector 700, and the second number may correspond to parameters (e.g., number of beamlets generated from charged-particle source 202 in FIG. 2) of beam tool 104 of FIGS. 1-2. Digital switch 740 may communicate with external components via data line(s) and address signal(s). In some embodiments, digital switch 740 may control data read/write. Digital switch 740 may also include circuitry for controlling the inter-element switches 715. In FIG. 7, digital switch 740 may generate output signals via multiple data channels, including data channels 751a-n. In some embodiments, the data channels of digital switch 708 may be further connected to other components (e.g., relays or the like). Thus, multiple sections of detector 700 may act as independent data channels for detector signals.

It is noted that various components may be inserted at various stages in the representation of FIG. 7. In some embodiments, one or more of the above components of detector 700 may be omitted. In some embodiments, other circuits may be provided for other functions. For example, switch-element actuating circuits (not shown in FIG. 7) may be provided to control inter-element switches 715 for connecting the sensing elements. In some embodiments, an analog output line (not shown in FIG. 7) may be provided, which can be read by an analog path. For example, the analog output line may be parallel to data converter 706 for receiving output of a post-amplifier. For another example, the analog output line may replace data converter 706.

Similar to interconnect layer 416 in FIG. 4, detector 700 may include an interconnection layer 716 (represented by the dashed line box) that is arranged between the amplifiers 704 and the ADCs 706. Amplifiers 704 may be communicatively coupled to interconnection layer 716 via switches 710, which may be similar to switch 410 in FIG. 4. Interconnection layer 716 may be communicatively coupled to the ADCs via switches 712, which may be similar to switch 412 in FIG. 4. In some embodiments, switches 709, 710, 712, and 731-733 may be implemented using techniques similar to switches 519 and 521 as described in FIG. 6.

Interconnection layer 716 may include multiple outputs, including an I/O points 726. In some embodiments, I/O points 726 may be similar to I/O point 426 in FIG. 4. In some embodiments, each of the amplifiers 704 of detector 700 may be communicatively coupled to an input 726 of interconnection layer 716 via a switch 710. In some embodiments, each of the ADCs 706 of detector 700 may be communicatively coupled to an output (e.g., an I/O point 726) of interconnection layer 716 via a switch 712.

In FIG. 7, interconnection layer 716 includes interconnection switches (e.g., interconnection switches 731-733) communicatively coupled to outputs of the amplifiers, which may be similar to interconnection switches 430-433 in FIG. 4. In some embodiments, the interconnection switches in interconnection layer 716 may be implemented using techniques similar to switches 519 and 521 as described in FIG. 6.

In some embodiments, for increasing the pixel rate, the ADCs of detector 700 may be configured to work in an interleaving mode. Generally, when ADCs work in the interleaving mode, two or more ADCs may be communicatively coupled to a clocking circuit. The clocks of the ADCs may be set to have a predetermined relationship. When operating, the ADCs may alternately sample (“interleave”) an input signal and generate a combined output signal. The pixel rate of the combined output signal may be higher than a pixel rate achieved by each individual ADC. For example, when m (m being an integer) ADCs are configured to work in the interleaving mode, in which each ADC has a pixel rate of n (n being a number) pixels per second, the combined pixel rate of the m ADCs may be m×n pixels per second.

For example, a clocking circuit (not shown in FIG. 7) and a control circuit (not shown in FIG. 7) may be provided in digital switch 708. A clock control may be provided in each ADC, including ADCs 706a-n. The clock control circuit may be communicatively coupled to the clocking circuit and may set different timing shifts for each ADC with reference to a clock signal generated by the clocking circuit. The inputs of the ADCs may be communicatively coupled to each other via the switches in interconnection layer 716, and the control circuit may control them to work in the interleaving mode.

In some embodiments, for an application that requires a pixel rate higher than a pixel rate supported by the maximum sampling rate of the ADCs of detector 700, the ADCs may be configured to work in the interleaving mode. For example, ADCs 706a and 706b may have the same maximum sampling rate. When wiring paths 702a are activated (e.g., due to a charged-particle beam impinging on sensing elements 711a), switches 709a and 710a may be communicatively connected to enable the signal output by wiring paths 702a to be processed and amplified by amplifier 704a. Interconnection switch 731 and switches 712a and 712b may be coordinated to divert the amplified signal output by amplifier 704a to ADCs 706a and 706b in an alternate manner. For example, the amplified signal output by amplifier 704a may be diverted to ADC 706a by communicatively connecting switch 712a, and communicatively disconnecting interconnection switch 731 and switch 712b. The amplified signal output by amplifier 704a may be diverted to ADC 706b by communicatively disconnecting switch 712a, and communicatively connecting interconnection switch 731 and switch 712b. The control circuit and clocking circuit may control the timing of such diversions and the timing of sampling for ADCs 706a and 706b. The combined output signal of ADCs 706a and 706b may have an effective sampling rate twice that of the maximum sampling rate of any single ADC.

In should be noted that more than two ADCs of detector 700 may be configured to work in the interleaving mode in a similar manner, and this disclosure does not limit the embodiments of the interleaving mode to the above examples. In some embodiments, the communicatively coupled ADCs of detector 700 working in the interleaving mode may be either adjacent to each other or not adjacent to each other. For example, ADCs 706a, 706b, and 706n may be configured to work in the interleaving mode, in which the interconnection switches of interconnection layer 716 between them (e.g., including interconnection switch 731) and switches 712a-n may be coordinated to divert the amplified signal output by amplifier 704b to ADCs 706a-n in an alternate manner. For example, the amplified signal output by amplifier 704b may be diverted to ADC 706a by communicatively connecting switch 712a and interconnection switch 731, and communicatively disconnecting switch 712b, switch 712n, and one or more interconnection switches between ADCs 706b and 706n. The amplified signal output by amplifier 704b may be diverted to ADC 706b by communicatively connecting switch 712b, and communicatively disconnecting switch 712a, switch 712n, interconnection switch 731, and one or more interconnection switches between ADCs 706b and 706n. The amplified signal output by amplifier 704b may be diverted to ADC 706n by communicatively connecting switch 712n and all interconnection switches between ADCs 706b and 706n, and communicatively disconnecting switch 712a, switch 712b, and interconnection switch 731.

In some embodiments, when the beams impinging on detector 700 have a large beam spot, multiple analog signal paths of detector 700 may be configured to be communicatively coupled to a single ADC 706 via interconnection layer 716. For example, the analog signals from different analog signal paths may be summed or merged by hardware (e.g., at interconnection layer 716) before being input to any ADC 706. The summed analog signal may be converted by a single ADC 706. Such a design may reduce the needed digital output bandwidth and increase configuration flexibility. In contrast, existing designs of detectors may lack the capability of hardware-based analog signal summing before signal digitizing (e.g., due to analog signal path having no capability of outputting its signals to ADCs in other signal paths), and may require multiple digital output channels or bandwidth to process signals from the same large beam spot. Compared with existing designs, the design of detector 700 may provide a higher analog signal bandwidth without requiring additional digital output capacity or causing significant increase in sizes of readout circuits, because a single ADC may be sufficient to process an analog signal summed before its input with analog signals from multiple analog signal paths.

While FIG. 7 shows a full set of processing circuitry 704-706 for each section, this may not always be the case. In some embodiments of the present disclosure, each section within an array of sections (e.g., a 2×2 array) may have a dedicated amplifier 704, but there may be only one ADC 706 in the entire 2×2 array of sections. For example, within every 2×2 array of sections, there may be only one section having a direct (or “vertical”) connection to an ADC 706. In such a case, any sensing elements 711 within the remaining three sections must be connected laterally (e.g., via inter-element switches 715 in the lower hierarchy or interconnection switches 731-733 in the upper hierarchy) to a section that does have such processing circuitry in order to have their signals read out (although it need not be processing circuitry within their same array of sections). Alternatively, there may be only one amplifier as well as one ADC for an array of sections. Here, the one amplifier may be located downstream of I/O point 726 to allow amplification of signals that are diverted along the upper hierarchy as well as the lower hierarchy before the signals are passed on to an ADC 706. Thus, in a detector that is divided into 2×2 arrays of four sections each, with each section comprising, e.g., a 4×4 array of sixteen sensing elements, there may be an 8×8 grid of 64 sensing elements for each channel of processing circuitry 706 (or 704-706). It should be understood that the number of sections and sensing elements in this paragraph are given by way of example only.

For example, in some embodiments of the present disclosure, a first section of sensing elements 711a and a second section of sensing elements 711b may comprise a 2-section row in a 2×2 array of sections. The first section may include a direct (or “vertical”) path to processing circuitry 704a-706a, while the second section may not include all the processing circuitry shown in FIG. 7. For example, ADC 706b, or both amplifier 704b and ADC 706b, may be omitted (in the latter case, amplifier 706a may be located below I/O point 726a in FIG. 7). In this case, signals from sensing elements 711b may be passed to the processing circuitry of another section (such as ADC 706a or 706n) by using lateral switches, such as inter-element switches 715, or interconnection switches 731-733.

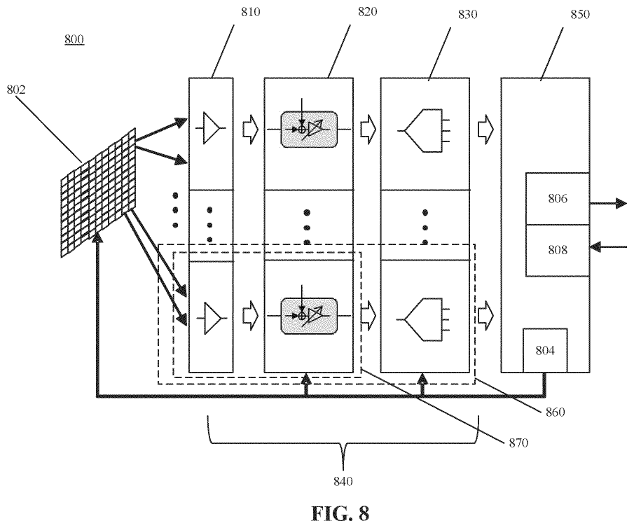

FIG. 8 is a diagram representing a detection system 800, consistent with embodiments of the present disclosure. In some embodiments, detection system 800 may be an embodiment of detection device 244 in FIG. 2. Detection system 800 may include sensing elements 802 (e.g., similar to the sensing elements as described in FIGS. 3A-7) and processing circuits 840 (e.g., similar to signal processing circuitry 704-706 in FIG. 7). Processing circuits 840 may be communicatively coupled to a digital interface 850 (e.g., similar to digital switch 708 in FIG. 7). Sensing elements 802 may form a sensor surface (e.g., sensor surface 300B of FIG. 3B), and may be segmented into sections (e.g., similar to the sections as described in FIGS. 3A-3B or FIG. 7). Processing circuits 840 may include a first processing circuit array 810 (e.g., including a pre-amplifier as discussed with respect to FIG. 7) for processing outputs of sensing elements 802, a second processing circuit array 820 (e.g., including post-amplifier as discussed with respect to FIG. 7) for providing gains and offset controls, and an ADC array 830 (e.g., including data converter 706 in FIG. 7) for converting analog signals to digital signals. The first processing circuit array 810 and the second processing circuit array 820 may form signal conditioning circuits in processing circuits 840. Each section of processing circuits 840 may be communicatively coupled to a section of sensing elements 802, which may be orderly, communicatively coupled to a unit of first processing circuit array 810, a unit of second processing circuit array 820, and a unit of ADC array 830, forming a signal path (e.g., signal path 860). Such a signal path may receive output signals from the section of sensing elements 802 and generate a charged-particle detection current representing the intensity of at least a portion of a charged-particle beam spot formed on the section of sensing elements 802. The charged-particle detection data may be output to digital interface 850. In FIG. 8, signal path 860 includes an analog signal path 870, which includes the unit of first processing circuit array 810 and the unit of second processing circuit array 820.

Digital interface 850 may include a controller 804. Controller 804 may communicate with ADC array 830, second processing circuit array 820, and sensing elements 802. Digital interface 850 can also send and receive communications from a deflection and image control unit (not shown in FIG. 8) via, for example, a transceiver. The transceiver may include a transmitter 806 and receiver 808. In some embodiments, controller 804 may control the image signal process of detection system 800.

Detectors may be configured to operate in multiple different operational modes. For instance, there may be a first mode called a “picture mode,” which is used to associate a part of the detector surface with a particular beam spot. A detector may include a large number of small sensing elements in the pixelated array. These sensing elements can be connected to each other in groups by a switch matrix to form combined signals when detecting an electron beam spot. However, when the sensing elements are grouped together by enabling switches between them, it is not possible to know exactly which sensing element any portion of the signal is coming from. So, each connected group should include only those elements that are expected to receive the same beam spot. Picture mode is a process used to determine the size, shape and location of each beam spot on the detector surface, in order to know which sensing elements should be grouped with each other during a normal detection process (called “beam mode”).

In picture mode, the detector surface may be irradiated with secondary beam spots while the output of each sensing element in the pixelated array is read individually. These individual readings can be used to determine every location on the detector surface that is receiving part of a beam spot. An image that represents a fine grain projection pattern of secondary beam spots on the detector surface may be formed (e.g., a secondary electron beam projection image). That is, fine grained image of the entire detector surface is generated. Based on this image, groups of sensing elements may be chosen such that the size, shape and location of each group substantially matches the size, shape and location of one of the beam spots on the detector surface. These chosen groups of sensing elements may be used later to detect their respective beam spots during beam mode.

In a “beam mode” during, e.g., an inspection process, sensing elements within each determined group are coupled to each other by the switch matrix, and their outputs may be merged with each other to acquire an intensity measurement of the secondary beam spot associated with the group. Thus, the picture mode may be useful for determining a boundary within which a desired grouping of sensing elements may be used during an inspection process in the beam mode. The switch matrix for interconnecting the sensing elements may include circuitry such as switches, wiring paths, and logical components between the sensing elements and readout circuitry of the detector. During beam mode, processing speed may be more important than high resolution. Due to “parasitic” effects, processing speed can be degraded by the amount of circuit components that are electrically connected to the system during detection, and well as the way they are connected. The more sensing elements, switches, etc. that are connected to a group during detection, the worse the parasitic effects may become.

A switch matrix according to embodiments of the present disclosure may be configured for improved bandwidth performance over comparative switch matrix embodiments. For example, detectors in a comparative embodiment may be configured to use different wiring paths for different operational modes, such as picture mode and beam mode. The different paths may include additional switches that may increase parasitic parameters within the system. Further, some configurations in a comparative embodiment may require the use of many lateral inter-element switches in series when routing signals from sensing elements along an analog signal path. This series-type configuration not only increases parasitic parameters by virtue of the series connections, but also by the requirements imposed upon the circuit elements by such operation. For example, when many sensing elements are expected to be connected in series, switches may be made larger to reduce ON-resistance of the series switches.

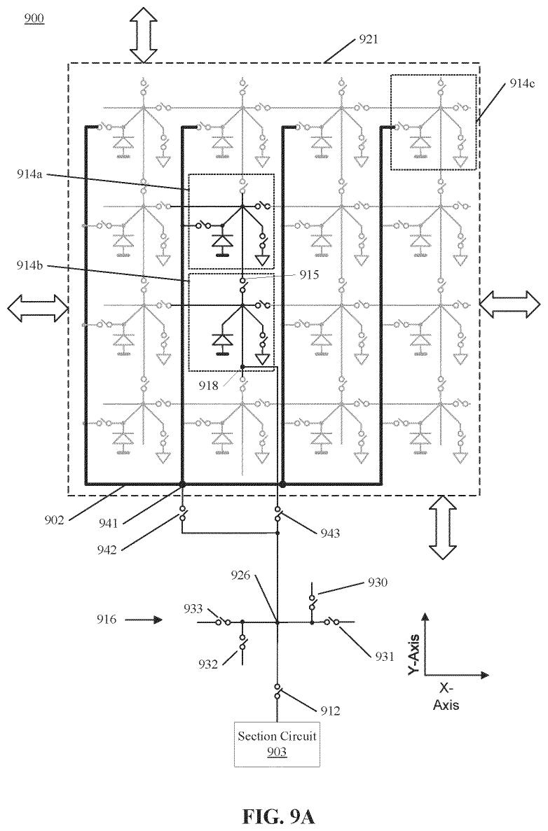

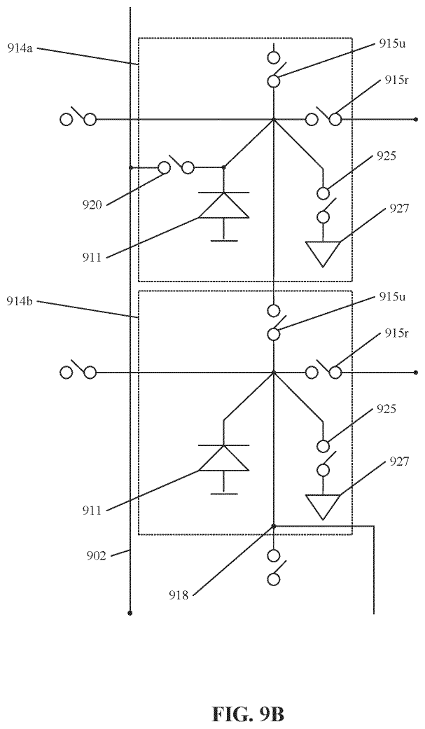

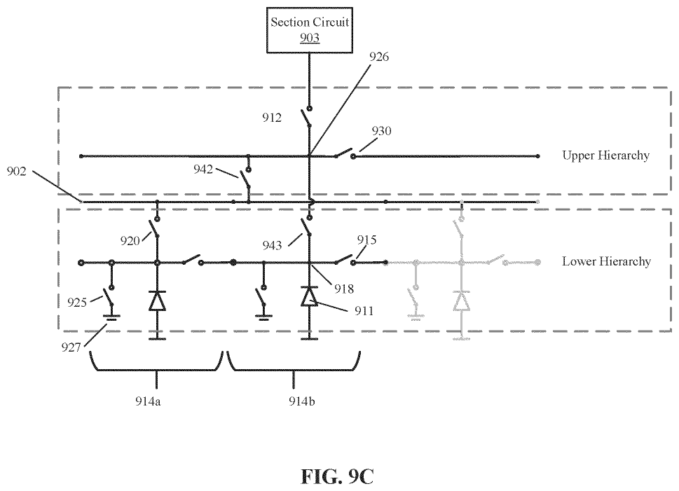

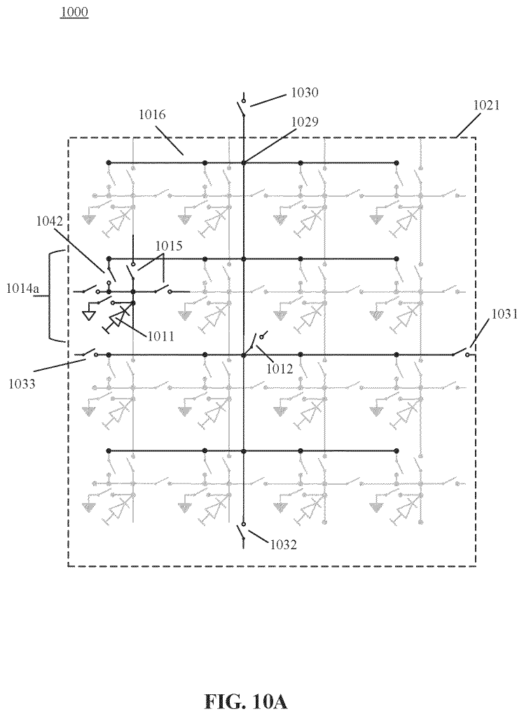

FIGS. 9A-C illustrate these issues with respect to a detector architecture according to a comparative embodiment. FIG. 9A illustrates a section 921 (enclosed by a dash-line box, similar to section 421 in FIG. 4) having a 4×4 array of sensing elements and related circuitry in a detector 900. Section 921 may be communicatively coupled to one or more other sections of detector array 900. In FIG. 9A, section 921 is communicatively coupled to four adjacent (or “neighboring”) sections (not shown in FIG. 9A) in its four planar directions (shown by double-headed arrows). Two “adjacent” objects along a direction herein may refer to two objects that have no intervening object arranged therebetween along the direction. Such object may be, for example, a section or a sensing element.

Section 921 may include a 4×4 array of sensing elements (e.g., similar to any of sensing elements 321-324 in FIG. 3A, any of sensing elements 511-513 in FIGS. 5-6, or any of sensing elements 711a-711n in FIG. 7). The sensing elements may be communicatively coupled to each other and to various signal paths by switches and other circuit components. Sensing element circuits (e.g., unit cells comprising a sensing element and associated switching elements and other circuitry) 914a and 914b are adjacent in the vertical (e.g., y-axis) direction. As shown in FIG. 9A, each sensing element circuit 914 within section 921 may have the same structure and operate in the same way, with the exception of sensing element circuit 914b. Other sections of detector 900 may have an identical or similar configuration to section 921.

Section 921 may further include an output bus 902 (shown as bold-black lines) that is a shared signal bus for receiving individual detection signals generated by the sensing elements. Output bus 902 may output the received signals independently via a bus output 941 to a section signal path or read out circuit. As shown in FIG. 9A, output bus 902 may output signals to a section circuit 903. Section circuit 903 may, for example, be included in any of sections 321-324 in FIG. 3A. A picture pickup switch 942 may be arranged between bus output 941 and section circuit 903. In some embodiments, when no signal is output at bus output 941, picture pickup switch 942 may be set as communicatively disconnected (e.g., open) for reducing parasitic parameters in signal processing. A further common output 918 may be communicatively coupled to a junction 926 via a section pickup switch 943. In some embodiments, junction 926 may be arranged in a sensor layer (e.g., sensor layer 301 in FIG. 3A) that includes the sensing elements of section 921.

FIG. 9B is a diagram illustrating a detailed view of the sensing element circuits 914a and 914b FIG. 9A, according to a comparative embodiment. With the exception of sensing element circuit 914b, all sensing element circuits in section 921 may form repeating unit cells that resemble sensing element circuit 914a.

Sensing element circuit 914a may comprise a sensing element 911 (e.g., a PIN diode), a picture mode switch 920, inter-element switches 915 (such as upper-element switch 915u and right-element switch 915r), ground switch 925, and ground 927. Sensing elements 911 of the comparative embodiment may correspond to, e.g., sensing elements 311-314 of FIG. 3A, 315-317 of FIG. 3B, 411 of FIG. 4, 511-513 of FIGS. 5 and 6, or 711a-n of FIG. 7. Sensing element 911 may be coupled to a signal readout path (activated) via, e.g., enabling picture mode switch 920 or inter-element switches 915 as further discussed below. Inter-element switches 915 may form a network of lateral switches in a lower hierarchy of a switch matrix. Sensing elements 911 may be decoupled from a signal readout path (deactivated) by, e.g., enabling ground switch 925 to send any signal generated at sensing element 911 to ground 927.

During a picture mode operation as discussed above, each sensing element 911 may be addressed individually to ascertain the size, shape, and location of beam spots on the surface of detector 900. Picture mode switch 920 may be used to communicatively couple sensing element 911 to output bus 902 during a picture mode operation. For instance, to individually address each sensing element 911 in section 921 of FIG. 9A, picture pickup switch 942 may be closed to couple output bus 902 to an analog signal path of the detector 900. With picture pickup switch 942 closed, each picture mode switch 920 may be successively closed and opened again to read a signal from each individual sensing element. When every picture mode switch 920 has been toggled on and off to address its respective sensing element 911, picture pickup switch 942 may be opened to isolate output bus 902 from interconnection layer 916 and section circuit 903. Only sensing element 914b, which does not have a picture mode switch 920, may be directly connected to a junction node 926 via section switch 943 when it is addressed. This process may be performed at other sections of detector, either concurrently or successively, to generate an image of all beam spots on the detector surface.

In beam mode, some or all of sensing elements 911 in section 921 may be grouped together in a common analog signal path. In the comparative embodiment of FIGS. 9A-C, this may be accomplished by coupling every grouped sensing element to common output 918 at sensing element circuit 914b. Grouped sensing elements may be coupled together using upper-element switches 915u and right-element switches 915r to send signals laterally through section 921. Then, as seen in FIG. 9A, common output 918 may be coupled to junction node 926 by enabling section switch 943.

This configuration may result in many sensing elements being connected in series. For example, sensing element circuit 914c is separated from sensing element 914b by two rows and two columns. Therefore, to couple sensing the element 911 in sensing element circuit 914c to common output 918, at least two upper-element switches 915u and two right-element switches 915r in the lower hierarchy would have to be closed. If sensing elements in an adjacent section were also grouped to the common output 918 of section 921, even more inter-element switches must be closed. Not only does this series connection arrangement increase parasitic parameters within the system, but it imposes structural requirements on the inter-element switches 915. Because it is expected that any sensing element circuit may become part of such a series connection, the switches must be made large enough to reduce their resistance below an acceptable level. The increased sized may contribute further parasitic parameters, such as parasitic capacitance.

The arrangement of this comparative embodiment also requires additional wiring paths, switches and other circuit components between lower and upper hierarchies that may contribute to parasitic parameters and reduce bandwidth performance. FIG. 9C illustrates a hierarchical view of detector 900 of FIGS. 9A-B according to a comparative embodiment. An upper hierarchy (in upper grey dashed box) may comprise interconnection switches, such as interconnection switch 930, for connecting adjacent sections to a common analog signal path. A lower hierarchy (in lower grey dashed box) may comprise inter-element switches 915 for connecting adjacent sensing elements to a common analog signal path. Between these two hierarchies is the output bus 902 for coupling individual sensing elements 911 to an analog signal path during picture mode via picture mode switches 920. Output bus 902 and picture pickup switch 942 may be considered intermediate components between the upper and lower hierarchies that, if eliminated, could reduce parasitic parameters and increase bandwidth performance. Bandwidth performance can further be improved by a switching arrangement that minimizes parasitic parameters by, e.g., reducing the use of inter-element switches.

FIGS. 10A-C illustrate an improved switch matrix configuration for a detector 1000, consistent with embodiments of the present disclosure. Detector 1000 may be an example of, e.g., detectors 244, 300A, 300B, 400, 500, 700, or 800 of FIGS. 2-8. In FIG. 10A, a 4×4 array of sensing element circuits comprises one section 1021 of detector 1000. An exemplary sensing element circuit 1014a is shown in black, while other sensing element circuits in section 1021 are shown in gray. Interconnection layer 1016 is also shown in black. Sensing element circuits 1014 (such as, e.g., an exemplary sensing element circuit 1014a) may comprise a sensing element 1011 (e.g., a PIN diode), inter-element switches 1015 for coupling to adjacent sensing element circuits, a grounding switch and ground (labels omitted for clarity) for deactivating sensing element 1011, and a pickup switch 1042 for coupling to interconnection layer 1016.

Interconnection layer 1016 may further comprise interconnection switches 1030-1033 for coupling to adjacent sections, and a readout switch 1012 for coupling section 1021 to signal processing circuitry (not shown in FIG. 10A). Signal processing circuitry may comprise, e.g., an amplifier 404 or ADC 406 as seen in FIG. 4. Readout switch 1012 may be similar to, e.g., switch 412 of FIG. 4 or switches 712a-n of FIG. 7. Readout switch 1012 may be located upstream or downstream of an amplifier (such as amplifier 404 of FIG. 4 or amplifiers 704a-n of FIG. 7). In some embodiments, further switches may be located on the input and output sides of signal processing circuitry. In some embodiments of the present disclosure, readout switch 1012 may not be provided within every section. For example, as discussed above with respect to FIG. 7, there may be one connection to signal processing circuitry (such as ADC 706 of FIG. 7) for every 2×2 array of sections in detector 1000. Sections that do not have dedicated signal processing circuitry may have their detection signals routed to a section that does.

The arrangement of FIG. 10A may provide improved bandwidth performance over the comparative embodiment of FIGS. 9A-C. The improvement may be realized in multiple different operating modes, such as, e.g., picture mode and beam mode.

For example, in FIGS. 9A-C, sensing elements 911 are connected to an intermediate output bus 902 during picture mode, which is then coupled to interconnection layer 916 by a single picture mode pickup switch 942. In contrast, elements 1011 may be directly coupled to interconnection layer 1016 via dedicated pickup switches 1042, with no intermediate output bus or picture mode switches. During a picture mode operation, each sensing element 1011 may be individually addressed by toggling its respective pickup switch 1042 on and off to connect the sensing element to interconnection layer 1016. If the sensing element 1011 is located within a section having a readout switch 1012 (such as section 1021), then the signal may be routed to signal processing circuitry by enabling the readout switch 1012. Alternatively, signals may be routed to signal processing circuitry in a nearby section by enabling the appropriate interconnection switches, such as switches 1030-1033. Thus, a picture mode operation may be realized with improved parasitic parameters in view of the streamlined architecture of FIG. 10A.

In beam mode, where signal processing speed is of great importance, the improved architecture of FIG. 10A allows for an optimal switching configuration to be chosen that maximizes bandwidth performance. For example, because every sensing element circuit 1014 may be directly coupled to a section node 1029 of the interconnection layer 1016 within its own section, there is a reduced need for lateral switching at inter-element switches 1015. In section 1021, an inter-element switch 1015 may be employed, e.g., only when its respective sensing element 1011 must be routed to signal processing circuitry other than that to which its own interconnection layer cell is coupled.

For instance, if the section node 1029 of interconnection layer 1016 within section 1021 is coupled to processing circuitry by readout switch 1012, but the sensing element 1011 within sensing element circuit 1014a is grouped with neighboring sensing elements in a different section to the left (not shown), then that sensing element may be coupled to the neighboring sensing elements via an inter-element switch 1015. However, if the sensing element 1011 within sensing element circuit 1014a is grouped with sensing elements that are coupled to readout switch 1012 by interconnection layer 1016, then it may be coupled by pickup switch 1042. In general, a sensing element 1011 in beam mode may be coupled via pickup switch 1042 whenever it is grouped in the same analog signal path as the section node 1029 of the upper hierarchy within its own section. Because pickup switches 1042 allow for more parallel connections than inter-element switches 1015, they may generally be preferred. However, the chosen switching configuration may ultimately depend on an optimization of total parasitic parameters in the system, rather than a default selection of pickup switch 1042 whenever it is available. Stated another way, it may be preferable under some circumstances to use an inter-element switch 1015 even when coupling by pickup switch 1042 is available.

FIG. 10B illustrates a hierarchical view of detector 1000 of FIG. 10A, consistent with embodiments of the present disclosure. An upper hierarchy (in upper grey dashed box) may comprise interconnection switches, such as interconnection switch 1030, for connecting adjacent sections to a common analog signal path. A lower hierarchy (in lower grey dashed box) may comprise inter-element switches 1015 for connecting adjacent sensing elements to a common analog signal path. Unlike FIG. 9C, there may be no intermediate output bus between the upper and lower hierarchies. Furthermore, unlike sensing element circuit 914b in FIG. 9C, all sensing element circuits in FIG. 10B may be substantially identical (compare e.g., differing sensing element circuits 914a/b of FIG. 9C to identical sensing element circuits 1014a/b of FIG. 10B). This is possible because there may be no need to provide a separate common output, such as 918 in FIGS. 9A-B, for use in beam mode. During beam mode, any sensing element that is grouped in a common analog signal path with the upper hierarchy of its own section may be directly coupled to the upper hierarchy at section node 1029 of via its respective pickup switch 1042. Inter-element switches 1015 in the lower hierarchy may be used to couple sensing elements to a neighboring analog signal path.

FIG. 10C illustrates a 2×2 array of sensing element sections of detector 1000, including section 1021 of FIG. 10A. consistent with embodiments of the present disclosure. In FIG. 10C, only section 1021 includes a readout switch 1012 to signal processing circuitry. However, more or fewer sections may include a readout switch 1012. As discussed above, interconnection layer 1016 (shown in black) may form repeating unit cells in an upper hierarchy of the switch matrix of detector 1000. For instance, section 1021 may comprise interconnection switch 1030 for coupling section 1021 to another section of sensing elements (not shown) above it in the plane of detector 1000, while interconnection switch 1031 may form a right switch that couples section 1021 to another section of sensing elements to the right in the plane (also not shown). Similarly, interconnection switch 1033 may constitute a right switch from the section to the left of section 1021, while interconnection switch 1032 may constitute a top switch from the section below section 1021 in the plane of detector 1000. A sensing element may be coupled to a section node 1029 of the upper hierarchy by enabling its associated pickup switch 1042, and may be further coupled to other nodes of the upper hierarchy by enabling interconnection switches, such as 1030-1033. In some embodiments, the upper hierarchy may comprise other interconnection switches such as, e.g., diagonal interconnection switches.

Sensing elements may also be coupled to each other by enabling inter-element switches 1015 in the lower hierarchy. For example, two sensing elements in the upper-left corner of section 1021 may be coupled to each other by enabling inter-element switch 1015a between them. These sensing elements may further be coupled to the next sensing element to left (in the adjacent section) by enabling inter-element switch 1015b. Thus, a group of sensing elements may form both inter- and intra-section couplings without using the upper hierarchy. However, there must be at least one upper-hierarchy connection in order to have signals read out at signal processing circuitry.

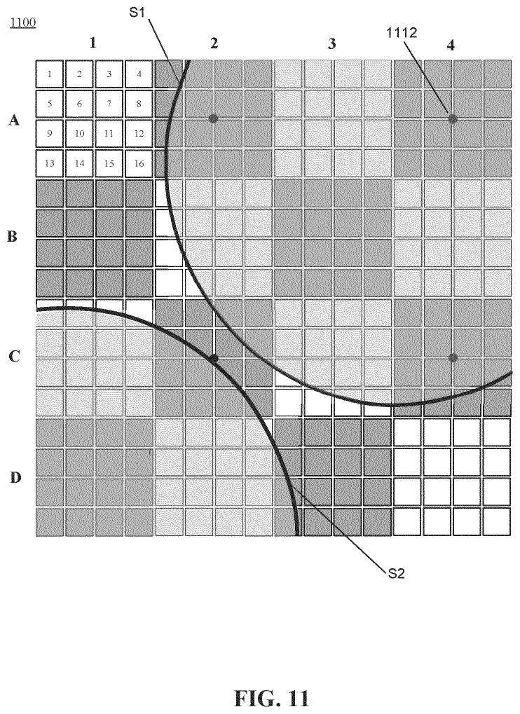

FIG. 11 is a diagram that illustrates different switching configurations on a portion of a detector surface 1100. Detector 1100 may be an example of, e.g., detectors 244, 300A, 300B, 400, 500, 700, 800 or 1000 of FIG. 2-8 or 10A-C. The illustrated portion of the surface of detector 1100 comprises sixteen sections arranged in rows A-D and columns 1-4, with each section comprising a 4×4 array of sensing elements. Within each section, individual sensing elements may be identified by number according to the labels shown in section A1. Sections are illustrated in alternating dark/light colors for clarity. Within each dark/light section, each sensing element may be coupled to a common section node by its respective pickup switch, such as shown in FIGS. 10A-C. As discussed above, some embodiments may provide a readout switch (such as readout switch 1012 of FIGS. 10A-C) and signal processing circuitry in every section, while other embodiments may not. In FIG. 11, every 2×2 array of sections may comprise one section that has a readout switch to signal processing circuitry. For instance, as illustrated by black dots, sections A2, A4, C2 and C4 may each be provided with a readout switch 1112 coupled to a channel of signal processing circuitry. The remaining sections may couple their sensing elements to the signal processing circuitry of another section by the hierarchical switch matrix of the present disclosure.

Two secondary beam spots S1 and S2 are incident on the illustrated portion of detector 1100. The size, shape, and location of spots S1 and S2 may be determined, e.g., during a picture mode operation. Sensing elements that are determined to fall within the borders of each spot may be grouped with each other for detection of the beam spot intensity during a beam mode operation such as, e.g., a SEM inspection process.

The size and placement of spots S1 and S2, as well as the size and number of sections and sensing elements, are provided for illustrative purposes only. In some embodiments, secondary beam spots S1, S2 may be larger or smaller in proportion to the sensing elements and sections of detector 1100. For example, a beam spot may not cover an entire section, or may not cover a section containing a readout switch 1012 (such as 1012 in FIGS. 10A-C). The beam spots may be spaced closer together or further apart, and their sizes and shapes may differ from each other. There may be more or fewer than two beam spots S1, S2 on the surface of detector 1100. The illustrative arrangement of FIG. 11 allows for discussion of some switching configurations that may be used in embodiments of the present disclosure.

Regarding spot S1, four sections (A3 A4, B3, B4) may have every sensing element coupled to its respective upper hierarchy layer in a common analog signal path by enabling their respective pickup switches (such as 1042 in FIGS. 10A-C). However, among these four sections, only A4 may comprise a readout switch. Therefore, sections A3, B3 and B4 may be coupled laterally at the upper hierarchy level (e.g., via interconnection switches 1030-1033 as seen in FIGS. 10A-C) to a section that includes a readout switch. For example, sections A3, B3 and B4 may be coupled to A2, A4 or C4 via lateral interconnection switches in the upper hierarchy. For reasons discussed below, section C2 may not be coupled to beam spot S1 at the upper hierarchy level even though it is provided with a readout switch.

Similarly, sensing elements in section A2 may be coupled to an upper hierarchy by their pickup switches. However, not every sensing element in section A1 is receiving a portion of spot S1. For instance, sensing element 1 in section A2 (i.e., sensing element A2-1) may be deactivated by disabling its pickup switch (and any inter-element switches) to reduce parasitic parameters in the system. Sensing element A2-1 may further be grounded (such as by a ground switch 1025 as seen in FIG. 10B) to prevent charge accumulation. Additionally, in some embodiments it may be determined that sensing element A2-5 is not receiving enough of spot S1 to warrant connecting it to the system. Therefore, in some embodiments, sensing element A2-5 may be similarly deactivated.

In section B2, all sensing elements aside from B2-9 and B2-13 may be coupled to the upper hierarchy via pickup switches and subsequently routed to, e.g., section A2 by a single interconnection switch for readout. Sensing elements B2-9 and B2-13 may be deactivated by disabling their pickup switches.

Section C2 presents a different situation because it is receiving portions of both spots S1 and S2. Here, the upper hierarchy layer within section C2 should be grouped only to one spot or the other. Therefore a decision must be made as to which spot will utilize the upper hierarchy layer of section C2, and which spot will have sensing elements coupled via inter-element switches of the lower hierarchy (such as switches 1015 of FIGS. 10A-B). Because more sensing elements of section C2 are assigned to spot S2, the decision may be made to assign the upper hierarchy of section C2 to spot S2. Additionally, sections C1, D1 and D2 may make use of the upper hierarchy layer to couple their sensing elements to the readout switch of section C2 (though it should be understood that other readout switches may be available in other sections located outside the illustrated area). Finally, sensing elements C2-3, C2-4, and C2-8 may be grouped with spot S1 by using inter-element switches in the lower hierarchy layer. For example, sensing element C2-4 may be coupled to sensing element B2-16 by enabling the inter-element switch between them.

It is important to note that out of all the sensing elements shown in FIG. 11, there may be as few as three (C2-3, C2-4, and C2-8) that are coupled by lower hierarchy switches. The exemplary switching configuration discussed above allows nearly every sensing element to be coupled “vertically” by parallel pickup switches to the upper hierarchy. By reducing the use of lateral inter-element switches, the amount of series connections may be reduced. Further, because the inter-element switches may be designed to support less current in view of the preferred switching configurations, the inter-element switches may be made smaller to further reduce parasitic parameters.

In some embodiments, a sensing element may be coupled to its group by lower hierarchy switches even when an upper hierarchy switch is available. For example, in FIG. 11, sensing elements D3-9 and D3-13 may be coupled via inter-element switches even though they could be coupled in another way, such as using pickup switches to the upper hierarchy and an interconnection switch to section D1. As discussed above, in some cases the bandwidth performance may be optimized by using inter-element switches of the lower hierarchy.

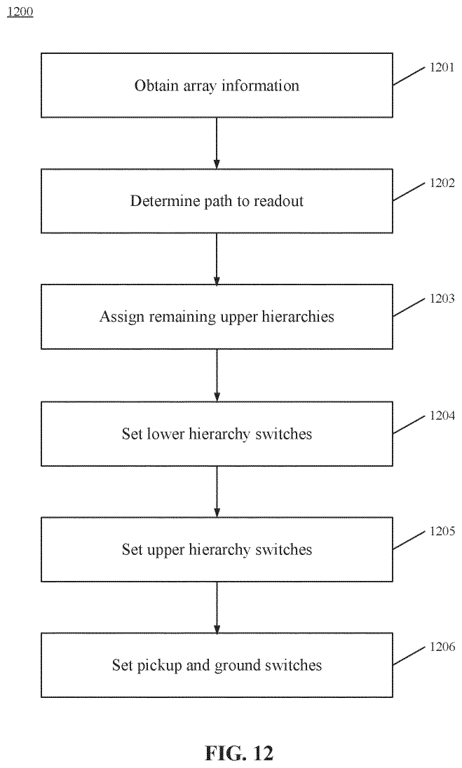

FIG. 12 illustrates an exemplary method 1200 for setting a switching configuration for beam spots on a detector, according to embodiments of the present disclosure. The detector may be, e.g., detectors 244, 300A, 300B, 400, 500, 700, 800, 1000 or 1100 of FIG. 2-8 or 10A-11. The method may be executed by a controller, such as controller 109 of FIG. 1 or controller 804 of FIG. 8).

At step 1201, the controller may obtain array information about the size, shape, and location of beam spots. The array information may alternatively or additionally include information about the grouping of each sensing element on the detector surface. For example, grouping information may comprise information about which sensing elements are assigned to which beam spot, and which sensing elements should be deactivated. Because each sensing element will be assigned to at most one beam spot, this information also determines which sensing elements may be grouped with each other. Groupings of sensing elements may generally be contiguous. However, in some embodiments a non-contiguous group of sensing elements may be assigned to a beam spot. The array information may be determined by, e.g., a picture mode operation.

At step 1202, the controller may use the array information to select appropriate sections of sensing elements that correspond to each beam spot, and determine appropriate paths to a readout switch for each beam spot. For example, the controller may select the closest available readout switch to a centroid (or geometric center) of a beam spot. The controller may then determine a path along the upper hierarchy to the readout switch from the centroid of the beam spot. In some embodiments, the closest available readout switch may be located in the same section as the centroid of the beam spot. In some embodiments, the closest available readout switch may be located in a different section. When the closest available readout switch is located on a diagonal section, the path may include interconnection switches through intervening sections in the horizontal or vertical directions. In some embodiments, the upper hierarchy may comprise diagonal connections.

At step 1203, upper hierarchies of remaining sections are assigned to the best fitting beam beam spot. For example, referring to FIG. 11, section A3 may be assigned to beam spot S1. Section A1 may be unassigned. Section C2 is receiving electrons from two beam spots S1 and S2. Because beam spot S2 is incident upon more sensing elements than beam spot S1, spot S2 may be considered the best fitting beam spot.

In some embodiments, there may be a threshold count of sensing elements below which no beam spot may be assigned to the upper hierarchy of a section. For example, if there are fewer than, e.g., four sensing elements receiving any single beam spot in section C2 of FIG. 11, the upper hierarchy within section C2 may remain unassigned (i.e., by opening all interconnection switches bordering section C2). In such a case, sensing elements in section C2 may be grouped by closing inter-element switches in the lower hierarchy. This threshold may be calculated according to a measure of parasitic parameters in the system. For instance, it may be determined that inter-element switches from only three sensing elements may contribute less to parasitic parameters than an upper hierarchy section would contribute. This threshold number may be weighted, e.g., according to series connections. For example, three sensing elements that are connected to an adjacent section in parallel (e.g., connecting sensing elements D3-5, 9, and 13 to section D2 in FIG. 11) may contribute less parasitic parameters than three sensing elements that are connected in series (e.g., connecting sensing elements C2-5, 9 and 13 to section D2).

At step 1204, the controller may set lower hierarchy switches. This may comprise, e.g., determining the appropriate open or closed state of each switch and actuating it accordingly. Alternatively, the process may proceed in phases.

In a first phase, the lower hierarchy may be set under an assumption that the upper hierarchy is not present. For example, in each sensing element circuit, the controller may close a right inter-element switch when the sensing element to the right is assigned to a same beam spot. Similarly, the controller may close a top inter-element switch when the sensing element above it is assigned to a same beam spot.

In a second phase, any closed inter-element switches that are deemed unnecessary may be opened. For example, when a first sensing element and a second sensing element to the right side of the first sensing element are both assigned to the same upper hierarchy path, the inter-element switch between them may be opened. The corresponding process may take place for sensing elements arranged in the perpendicular (upward) direction in the plane of the detector.

At step 1205, the controller may set upper hierarchy switches based on the upper hierarchy assignments in steps 1202-1203. For example, in each section, the controller may close a right interconnection switch when a section to the right is assigned to a same beam spot. Similarly, the controller may close a top interconnection switch when a section above it is assigned to a same beam spot. In some embodiments, redundant upper hierarchy switches may be eliminated. For example, if a 2×2 array of sections are all assigned to a same beam spot, such as sections A3, A4, B3, B4 in FIG. 11, then section B3 may have multiple upper-hierarchy paths to a readout switch in section A4. In some embodiments, all interconnection switches may be closed within this 2×2 array. In some embodiments, fewer than all interconnection switches may be closed.

At step 1206, the controller may set pickup and ground switches to activate or deactivate sensing elements. For example, for each sensing element that is assigned to a same beam spot as the interconnection layer cell within its section, its associated pickup switch may be closed to couple the sensing element to the upper hierarchy. At the same time, the ground switch associated with the sensing element may be opened. Thus, the sensing element may be activated. Other sensing elements may be activated by inter-element switches of the lower hierarchy at step 1204. For these sensing elements, both their pickup switches and ground switches may be opened.

Any unassigned sensing elements may be deactivated. Deactivation may include, e.g., opening switches that would couple the sensing element to the system, such as pickup switches 1042 or inter-element switches 1015 as seen in FIGS. 10A-C. An entire section may be deactivated by opening any interconnection switches that border the section.

The switching configuration may be selected to optimize bandwidth performance in the detector to improve signal processing speed. For instance, bandwidth performance may be optimized by minimizing parasitic parameters.

It should be understood that the above procedure is one of many possible methods for achieving a switching arrangement. The steps may be performed in a different order than what is described, or an entirely different set of steps may be employed. For example, instead of closing a set of lower hierarchy switches and subsequently opening any that are not needed, a switching method may comprise closing only those that switches are needed from the outset. In general, a static configuration of a switch matrix may be achieved by a wide variety of switching algorithms.

Embodiments of the present disclosure may be further described by the following clauses:
1. A method of configuring a switch matrix in a charged particle detector, comprising:
disabling a first inter-element switch between a first sensing element and a second sensing element of the charged particle detector to prevent charge from flowing between the first sensing element and the second sensing element via the first inter-element switch, the first inter-element switch forming part of a lower hierarchy of the switch matrix;
enabling a first pickup switch between the first sensing element and an upper hierarchy of the switch matrix to allow charge to flow between the first sensing element and the upper hierarchy via the first pickup switch; and
enabling a second pickup switch between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.
2. The method of clause 1, wherein:
the charged particle detector comprises a plurality of sensing elements including the first sensing element and the second sensing element;
the plurality of sensing elements is divided into a plurality of sections of sensing elements by an interconnection switch between each section of sensing elements; and
each interconnection switch of the plurality of interconnection switches forms part of the upper hierarchy.
3. The method of clause 2, wherein:
the first sensing element forms part of a first section of the plurality of sections; and
the second sensing element forms part of a second section of the plurality of sections;
the method further comprising:
enabling a first interconnection switch between the first section and the second section to couple the first sensing element and the second sensing element to a common analog signal path of the detector at the upper hierarchy.
4. The method of clause 3, wherein:
the upper hierarchy comprises a readout switch coupled to signal processing circuitry of the charged particle detector.
5. The method of clause 4, wherein:
the first interconnection switch is located between the first pickup switch and the readout switch on the common analog signal path;
the first interconnection switch is not located between the second pickup switch and the readout switch on the common analog signal path.
6. The method of clause 2, wherein:
the first sensing element and the second sensing element form part of a first section of the plurality of sections;
the first sensing element is coupled to the common analog signal path of the detector at a first node of the upper hierarchy by the first pickup switch; and
the second sensing element is coupled to the common analog signal path of the detector at the first node of the upper hierarchy by the second pickup switch.
7. The method of clause 6, further comprising:
enabling a second inter-element switch between the second sensing element and a third sensing element of the charged particle detector to allow charge to flow between the third sensing element and the second sensing element via the second inter-element switch, the second inter-element switch forming part of the lower hierarchy; wherein:
the third sensing element forms part of a second section of the plurality of sections.
8. The method of clause 7, further comprising:
disabling a third pickup switch between the third sensing element and a second node of the upper hierarchy to prevent charge from flowing between the third sensing element and the second node via the third pickup switch.
9. The method of clause 6, further comprising:
disabling a third pickup switch between a third sensing element and the first node to prevent charge from flowing between the third sensing element and the first node via the third pickup switch;
enabling a ground switch between the third sensing element and a ground connection to prevent charge from accumulating at the third sensing element,
wherein the third sensing element forms part of the first section of the plurality of sections.
10. The method of clause 1, wherein the first sensing element and the second sensing element comprise PIN diodes.
11. The method of clause 1, wherein the charged particle detector is part of a charged particle beam system.
12. The method of clause 11, wherein the charged particle beam system is a SEM inspection tool.
13. The method of clause 1, further comprising:
determining a size, shape, or location of a beam spot on a surface of the charged particle detector;
assigning the first sensing element and the second sensing element to the common analog signal path based on the determined size, shape, or location of the beam spot; and
selecting a switching configuration based on the assignment;
wherein the switching configuration comprises the disabled first inter-element switch, the enabled first pickup switch, and the enabled second pickup switch.
14. The method of clause 13, wherein the switching configuration is selected based on a parasitic parameter of the switching configuration.
15. A non-transitory computer-readable medium that stores a set of instructions that is executable by at least one processor of an apparatus to cause the apparatus to perform a method, the method comprising:
disabling a first inter-element switch between a first sensing element and a second sensing element of the charged particle detector to prevent charge from flowing between the first sensing element and the second sensing element via the first inter-element switch, the first inter-element switch forming part of a lower hierarchy of a switch matrix;
enabling a first pickup switch between the first sensing element and an upper hierarchy of the switch matrix to allow charge to flow between the first sensing element and the upper hierarchy via the first pickup switch; and
enabling a second pickup switch between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.
16. The non-transitory computer-readable medium of clause 15, wherein:
the charged particle detector comprises a plurality of sensing elements including the first sensing element and the second sensing element;
the plurality of sensing elements is divided into a plurality of sections of sensing elements by an interconnection switch between each section of sensing elements; and
each interconnection switch of the plurality of interconnection switches forms part of the upper hierarchy.
17. The non-transitory computer-readable medium of clause 16, wherein:
the first sensing element forms part of a first section of the plurality of sections; and
the second sensing element forms part of a second section of the plurality of sections;
wherein the set of instructions that is executable by the at least one processor of the apparatus causes the apparatus to further perform
enabling a first interconnection switch between the first section and the second section to couple the first sensing element and the second sensing element to a common analog signal path of the detector at the upper hierarchy.
18. The non-transitory computer-readable medium of clause 17, wherein:
the upper hierarchy comprises a readout switch coupled to signal processing circuitry of the charged particle detector.
19. The non-transitory computer-readable medium of clause 18, wherein:
the first interconnection switch is located between the first pickup switch and the readout switch on the common analog signal path; and
the first interconnection switch is not located between the second pickup switch and the readout switch on the common analog signal path.
20. The non-transitory computer-readable medium of clause 16, wherein:
the first sensing element and the second sensing element form part of a first section of the plurality of sections;
the first sensing element is coupled to the common analog signal path of the detector at a first node of the upper hierarchy by the first pickup switch; and
the second sensing element is coupled to the common analog signal path of the detector at the first node by the second pickup switch.
21. The non-transitory computer-readable medium of clause 20, wherein the set of instructions that is executable by the at least one processor of the apparatus causes the apparatus to further perform:
enabling a second inter-element switch between the second sensing element and a third sensing element of the charged particle detector to allow charge to flow between the third sensing element and the second sensing element via the second inter-element switch, the second inter-element switch forming part of the lower hierarchy; wherein:
the third sensing element forms part of a second section of the plurality of sections.
22. The non-transitory computer-readable medium of clause 21, wherein the set of instructions that is executable by the at least one processor of the apparatus causes the apparatus to further perform:
disabling a third pickup switch between the third sensing element and a second node of the upper hierarchy to prevent charge from flowing between the third sensing element and the second node via the third pickup switch.
23. The non-transitory computer-readable medium of clause 20, wherein the set of instructions that is executable by the at least one processor of the apparatus causes the apparatus to further perform:
disabling a third pickup switch between a third sensing element and the first node to prevent charge from flowing between the third sensing element and the first node via the third pickup switch; and
enabling a ground switch between the third sensing element and a ground connection to prevent charge from accumulating at the third sensing element,
wherein the third sensing element forms part of the first section of the plurality of sections.
24. The non-transitory computer-readable medium of clause 15, wherein the first sensing element and the second sensing element comprise PIN diodes.
25. The non-transitory computer-readable medium of clause 15, wherein the charged particle detector is part of a charged particle beam system.
26. The non-transitory computer-readable medium of clause 25, wherein the charged particle beam system is a SEM inspection tool.
27. The non-transitory computer-readable medium of clause 15, wherein the set of instructions that is executable by the at least one processor of the apparatus causes the apparatus to further perform:
determining a size, shape or location of a beam spot on a surface of the charged particle detector;
assigning the first sensing element and the second sensing element to the common analog signal path based on the determined size, shape or location of the beam spot; and
selecting a switching configuration based on the assignment;
wherein the switching configuration comprises the disabled first inter-element switch, the enabled first pickup switch, and the enabled second pickup switch.
28. The non-transitory computer-readable medium of clause 27, wherein the switching configuration is selected based a parasitic parameter of the switching configuration.
29. A charged particle beam apparatus, comprising:
a charged particle beam source configured to generate a beam of primary charged particles;
a charged particle optical system configured to direct the beam of primary charged particles at a sample surface to inspect the sample surface;
a charged particle detector configured to detect charged particles returned from the sample surface,
wherein the charged particle detector comprises a first sensing element and a second sensing element; and
a controller comprising one or more processors and configured to cause the charged particle beam apparatus to perform a method comprising:
disabling a first inter-element switch between the first sensing element and the second sensing element to prevent charge from flowing between the first sensing element and the second sensing element via the first inter-element switch, the first inter-element switch forming part of a lower hierarchy of a switch matrix;
enabling a first pickup switch between the first sensing element and an upper hierarchy of the switch matrix to allow charge to flow between the first sensing element and the upper hierarchy via the first pickup switch; and
enabling a second pickup switch between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.
30. The charged particle beam apparatus of clause 29, wherein:
the charged particle detector comprises a plurality of sensing elements including the first sensing element and the second sensing element;
the plurality of sensing elements is divided into a plurality of sections of sensing elements by an interconnection switch between each section of sensing elements; and
each interconnection switch of the plurality of interconnection switches forms part of the upper hierarchy.
31. The charged particle beam apparatus of clause 30, wherein:
the first sensing element forms part of a first section of the plurality of sections;
the second sensing element forms part of a second section of the plurality of sections; and
the first sensing element and the second sensing element are coupled to a common analog signal path of the detector at the upper hierarchy by enabling a first interconnection switch between the first section and the second section.
32. The charged particle beam apparatus of clause 31, wherein:
the upper hierarchy comprises a readout switch coupled to signal processing circuitry of the charged particle detector.
33. The charged particle beam apparatus of clause 32, wherein:
the first interconnection switch is located between the first pickup switch and the readout switch on the common analog signal path;
the first interconnection switch is not located between the second pickup switch and the readout switch on the common analog signal path.
34. The charged particle beam apparatus of clause 30, wherein:
the first sensing element and the second sensing element form part of a first section of the plurality of sections;
the first sensing element is coupled to the common analog signal path of the detector at a first node of the upper hierarchy by the first pickup switch; and
the second sensing element is coupled to the common analog signal path of the detector at the first node of the upper hierarchy by the second pickup switch.
35. The charged particle beam apparatus of clause 34, wherein the controller is further configured to cause the charged particle beam apparatus to perform:
enabling a second inter-element switch between the second sensing element and a third sensing element of the charged particle detector to allow charge to flow between the third sensing element and the second sensing element via the second inter-element switch, the second inter-element switch forming part of the lower hierarchy; wherein:
the third sensing element forms part of a second section of the plurality of sections.
36. The charged particle beam apparatus of clause 35, wherein the controller is further configured to cause the charged particle beam apparatus to perform:
disabling a third pickup switch between the third sensing element and a second node of the upper hierarchy to prevent charge from flowing between the third sensing element and the second node via the third pickup switch.
37. The charged particle beam apparatus of clause 29, wherein the controller is further configured to cause the charged particle beam apparatus to perform:
disabling a third pickup switch between a third sensing element and the first node to prevent charge from flowing between the third sensing element and the first node via the third pickup switch; and
enabling a ground switch between the third sensing element and a ground connection to prevent charge from accumulating at the third sensing element,
wherein the third sensing element forms part of the first section of the plurality of sections.
38. The charged particle beam apparatus of clause 29, wherein the first sensing element and the second sensing element comprise PIN diodes.
39. The charged particle beam apparatus of clause 29, wherein the charged particle detector is part of a charged particle beam system.
40. The charged particle beam apparatus of clause 39, wherein the charged particle beam system is a SEM inspection tool.
41. The charged particle beam apparatus of clause 29, wherein the controller is further configured to cause the charged particle beam apparatus to perform:
determining a size, shape or location of a beam spot on a surface of the charged particle detector;
assigning the first sensing element and the second sensing element to the common analog signal path based on the determined size, shape or location of the beam spot; and
selecting a switching configuration based on the assignment;
wherein the switching configuration comprises the disabled first inter-element switch, the enabled first pickup switch, and the enabled second pickup switch.
42. The charged particle beam apparatus of clause 41, wherein the switching configuration is selected based on a parasitic parameter of the switching configuration.
43. A method of configuring a switch matrix in a charged particle detector, comprising:
enabling a first pickup switch between a first sensing element and a first node of an upper hierarchy of the switch matrix to allow charge to flow between the first sensing element and the first node via the first pickup switch, the first sensing element receiving charged particles of a first beam spot;
enabling a first inter-element switch between a second sensing element and a third sensing element to allow charge to flow between the second sensing element and the third sensing element via the first inter-element switch, the second sensing element and the third sensing element receiving charged particles of a second beam spot;
disabling a second pickup switch between the second sensing element and the first node to prevent charge from flowing between the second sensing element and the first node via the pickup switch; and
enabling a third pickup switch between the third sensing element and a second node of the upper hierarchy of the switch matrix to allow charge to flow between the third sensing element and the second node via the third pickup switch.
44. The method of clause 43, wherein
the first node is a common node of the upper hierarchy in a first section of sensing elements, the first section comprising the first sensing element and the second sensing element; and
the second node is a common node of the upper hierarchy in a second section of sensing elements, the second section comprising the third sensing element.
45. The method of clause 44, further comprising:
disabling a first interconnection switch between the first node and the second node to prevent charge from flowing in the upper hierarchy between the first node and the second node via the first interconnection switch.
46. The method of clause 43, further comprising:
disabling a second inter-element switch between a fourth sensing element and at least one of the first sensing element and the second sensing element to prevent charge from flowing between the fourth sensing element and at least one of the first sensing element and the second sensing element; and
disabling a fourth pickup switch between the fourth sensing element and the first node to prevent charge from flowing between the fourth sensing element and the first node via the fourth pickup switch.
47. The method of clause 43, further comprising:
enabling a first readout switch between the upper hierarchy and first signal processing circuitry to allow a first signal to reach the first signal processing circuitry, the first signal representing at least the charge from the first sensing element; and
enabling a second readout switch between the upper hierarchy and second signal processing circuitry to allow a second signal to reach the second signal processing circuitry, the second signal representing at least the charge from the second sensing element.
48. The method of clause 47, wherein one of the first signal processing circuitry and the second signal processing circuitry comprises and analog-to-digital converter (ADC).
49. The method of clause 47, further comprising:
determining a first characteristic of the first beam spot based on the first signal; and
determining a second characteristic of the second beam spot based on the second signal.
50. The method of clause 49, wherein:
the first characteristic comprises an intensity of the first beam spot; and
the second characteristic comprises an intensity of the second beam spot.
51. A non-transitory computer-readable medium that stores a set of instructions that is executable by at least one processor of an apparatus to cause the apparatus to perform a method, the method comprising:
enabling a first pickup switch between a first sensing element and a first node of an upper hierarchy of a switch matrix to allow charge to flow between the first sensing element and the first node via the first pickup switch, the first sensing element configured to receive charged particles of a first beam spot;
enabling a first inter-element switch between a second sensing element and a third sensing element to allow charge to flow between the second sensing element and the third sensing element via the first inter-element switch, the second sensing element and the third sensing element configured to receive charged particles of a second beam spot;
disabling a second pickup switch between the second sensing element and the first node to prevent charge from flowing between the second sensing element and the first node via the pickup switch; and
enabling a third pickup switch between the third sensing element and a second node of the upper hierarchy of the switch matrix to allow charge to flow between the third sensing element and the second node via the third pickup switch.
52. The non-transitory computer-readable medium of clause 51, wherein
the first node is a common node of the upper hierarchy in a first section of sensing elements, the first section comprising the first sensing element and the second sensing element; and
the second node is a common node of the upper hierarchy in a second section of sensing elements, the second section comprising the third sensing element.
53. The non-transitory computer-readable medium of clause 52, wherein the set of instructions that is executable by the at least one processor of the apparatus causes the apparatus to further perform:
disabling a first interconnection switch between the first node and the second node to prevent charge from flowing in the upper hierarchy between the first node and the second node via the first interconnection switch.
54. The non-transitory computer-readable medium of clause 51, wherein the set of instructions that is executable by the at least one processor of the apparatus causes the apparatus to further perform:
disabling a second inter-element switch between a fourth sensing element and at least one of the first sensing element and the second sensing element to prevent charge from flowing between the fourth sensing element and at least one of the first sensing element and the second sensing element; and
disabling a fourth pickup switch between the fourth sensing element and the first node to prevent charge from flowing between the fourth sensing element and the first node via the fourth pickup switch.
55. The non-transitory computer-readable medium of clause 51, wherein the set of instructions that is executable by the at least one processor of the apparatus causes the apparatus to further perform:
enabling a first readout switch between the upper hierarchy and first signal processing circuitry to allow a first signal to reach the first signal processing circuitry, the first signal representing at least the charge from the first sensing element; and
enabling a second readout switch between the upper hierarchy and second signal processing circuitry to allow a second signal to reach the second signal processing circuitry, the second signal representing at least the charge from the second sensing element.
56. The non-transitory computer-readable medium of clause 55, wherein one of the first signal processing circuitry and the second signal processing circuitry comprises and analog-to-digital converter (ADC).
57. The non-transitory computer-readable medium of clause 55, wherein the set of instructions that is executable by the at least one processor of the apparatus causes the apparatus to further perform:
determining a first characteristic of the first beam spot based on the first signal; and
determining a second characteristic of the second beam spot based on the second signal.
58. The non-transitory computer-readable medium of clause 57, wherein:
the first characteristic comprises an intensity of the first beam spot; and
the second characteristic comprises an intensity of the second beam spot.
59. A charged particle beam apparatus, comprising:
a charged particle beam source configured to generate a beam of primary charged particles;
a charged particle optical system configured to direct the beam of primary charged particles at a sample surface to inspect the sample surface;
a charged particle detector configured to detect charged particles returned from the sample surface; and
a controller comprising one or more processors and configured to cause the charged particle beam apparatus to perform a method comprising:
enabling a first pickup switch between a first sensing element and a first node of an upper hierarchy of the switch matrix to allow charge to flow between the first sensing element and the first node via the first pickup switch, the first sensing element configured to receive charged particles of a first beam spot;
enabling a first inter-element switch between a second sensing element and a third sensing element to allow charge to flow between the second sensing element and the third sensing element via the first inter-element switch, the second sensing element and the third sensing element configured to receive charged particles of a second beam spot;
disabling a second pickup switch between the second sensing element and the first node to prevent charge from flowing between the second sensing element and the first node via the pickup switch; and
enabling a third pickup switch between the third sensing element and a second node of the upper hierarchy of the switch matrix to allow charge to flow between the third sensing element and the second node via the third pickup switch.
60. The charged particle beam apparatus of clause 59, wherein:
the first node is a common node of the upper hierarchy in a first section of sensing elements, the first section comprising the first sensing element and the second sensing element; and
the second node is a common node of the upper hierarchy in a second section of sensing elements, the second section comprising the third sensing element.
61. The charged particle beam apparatus of clause 60, wherein the controller is further configured to cause the charged particle beam apparatus to perform:
disabling a first interconnection switch between the first node and the second node to prevent charge from flowing in the upper hierarchy between the first node and the second node via the first interconnection switch.
62. The charged particle beam apparatus of clause 59, wherein the controller is further configured to cause the charged particle beam apparatus to perform:
disabling a second inter-element switch between a fourth sensing element and at least one of the first sensing element and the second sensing element to prevent charge from flowing between the fourth sensing element and at least one of the first sensing element and the second sensing element; and
disabling a fourth pickup switch between the fourth sensing element and the first node to prevent charge from flowing between the fourth sensing element and the first node via the fourth pickup switch.
63. The charged particle beam apparatus of clause 59, wherein the controller is further configured to cause the charged particle beam apparatus to perform:
enabling a first readout switch between the upper hierarchy and first signal processing circuitry to allow a first signal to reach the first signal processing circuitry, the first signal representing at least the charge from the first sensing element; and
enabling a second readout switch between the upper hierarchy and second signal processing circuitry to allow a second signal to reach the second signal processing circuitry, the second signal representing at least the charge from the second sensing element.
64. The charged particle beam apparatus of clause 63, wherein one of the first signal processing circuitry and the second signal processing circuitry comprises and analog-to-digital converter (ADC).
65. The charged particle beam apparatus of clause 63, wherein the controller is further configured to cause the charged particle beam apparatus to perform:
determining a first characteristic of the first beam spot based on the first signal; and
determining a second characteristic of the second beam spot based on the second signal.
66. The charged particle beam apparatus of clause 65, wherein:
the first characteristic comprises an intensity of the first beam spot; and
the second characteristic comprises an intensity of the second beam spot.
67. A charged particle detector having a switch matrix comprising an upper hierarchy and a lower hierarchy, the charged particle detector comprising:
a plurality of sections, each section comprising a plurality of sensing element circuits arranged in an array, each sensing element circuit comprising:
a sensing element configured to generate charge from a charged particle landing event at the sensing element;
a pickup switch configured to couple the sensing element to a node of the upper hierarchy of the switch matrix in the section; and
an inter-element switch configured to couple the sensing element to an adjacent sensing element to allow charge to flow between the sensing element and the adjacent sensing element, the inter-element switch forming part of the lower hierarchy;
wherein within each section of the plurality of sections, each sensing element is configured to be coupled to a common node of the upper hierarchy in the section by its respective pickup switch.
68. The charged particle detector of clause 67, further comprising an interconnection switch in the upper hierarchy between each pair of adjacent sections in the plurality of sections.
69. The charged particle detector of clause 67, further comprising an inter-section inter-element switch between each pair of adjacent sensing elements that span two adjacent sections, each inter-section inter-element switch forming part of the lower hierarchy.
70. A charged particle beam apparatus, comprising:
a charged particle beam source configured to generate a beam of primary charged particles;
a charged particle optical system configured to direct the beam of primary charged particles at a sample surface to inspect the sample surface;
a charged particle detector configured to detect charged particles returned from the sample surface,
wherein the charged particle detector comprises a first sensing element and a second sensing element;
a first inter-element switch that is configured to be disabled between the first sensing element and the second sensing element to prevent charge from flowing between the first sensing element and the second sensing element via the first inter-element switch, the first inter-element switch forming part of a lower hierarchy of a switch matrix;
a first pickup switch that is configured to be enabled between the first sensing element and an upper hierarchy of the switch matrix to allow charge to flow between the first sensing element and the upper hierarchy via the first pickup switch; and
a second pickup switch that is configured to be disabled between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.
71. The charged particle beam apparatus of clause 70, wherein:
the charged particle detector comprises a plurality of sensing elements including the first sensing element and the second sensing element;
the plurality of sensing elements is divided into a plurality of sections of sensing elements by an interconnection switch between each section of sensing elements; and
each interconnection switch of the plurality of interconnection switches forms part of the upper hierarchy.
72. The charged particle beam apparatus of clause 71, wherein:
the first sensing element forms part of a first section of the plurality of sections;
the second sensing element forms part of a second section of the plurality of sections; and
the first sensing element and the second sensing element are coupled to a common analog signal path of the detector at the upper hierarchy by enabling a first interconnection switch between the first section and the second section.
73. The charged particle beam apparatus of clause 72, wherein:
the upper hierarchy comprises a readout switch coupled to signal processing circuitry of the charged particle detector.
74. The charged particle beam apparatus of clause 73, wherein:
the first interconnection switch is located between the first pickup switch and the readout switch on the common analog signal path; and
the first interconnection switch is not located between the second pickup switch and the readout switch on the common analog signal path.
75. The charged particle beam apparatus of clause 71, wherein:
the first sensing element and the second sensing element form part of a first section of the plurality of sections;
the first sensing element is coupled to the common analog signal path of the detector at a first node of the upper hierarchy by the first pickup switch; and
the second sensing element is coupled to the common analog signal path of the detector at the first node of the upper hierarchy by the second pickup switch.
76. The charged particle beam apparatus of clause 75, further comprising:
a second inter-element switch that is configured to be enabled between the second sensing element and a third sensing element of the charged particle detector to allow charge to flow between the third sensing element and the second sensing element via the second inter-element switch, the second inter-element switch forming part of the lower hierarchy; wherein:
the third sensing element forms part of a second section of the plurality of sections.
77. The charged particle beam apparatus of clause 76, further comprising:
a third pickup switch that is configured to be disabled between the third sensing element and a second node of the upper hierarchy to prevent charge from flowing between the third sensing element and the second node via the third pickup switch.
78. The charged particle beam apparatus of clause 70, further comprising:
a third pickup switch that is configured to be disabled between a third sensing element and the first node to prevent charge from flowing between the third sensing element and the first node via the third pickup switch; and
a ground switch that is configured to be enabled between the third sensing element and a ground connection to prevent charge from accumulating at the third sensing element,
wherein the third sensing element forms part of the first section of the plurality of sections.
79. The charged particle beam apparatus of clause 70, wherein the first sensing element and the second sensing element comprise PIN diodes.
80. The charged particle beam apparatus of clause 70, further comprising:
a charged particle beam system;
wherein the charged particle detector is part of the charged particle beam system.
81. The charged particle beam apparatus of clause 80, wherein the charged particle beam system is a SEM inspection tool.
82. The charged particle beam apparatus of clause 70, wherein the charged particle beam apparatus is configured to:
determine a size, shape or location of a beam spot on a surface of the charged particle detector;
assign the first sensing element and the second sensing element to the common analog signal path based on the determined size, shape or location of the beam spot; and
select a switching configuration based on the assignment;
wherein the switching configuration comprises the disabled first inter-element switch, the enabled first pickup switch, and the enabled second pickup switch.
83. The charged particle beam apparatus of clause 82, wherein the charged particle beam apparatus is configured to select the switching configuration based on a parasitic parameter of the switching configuration.
84. A charged particle beam apparatus, comprising:
a charged particle beam source configured to generate a beam of primary charged particles;
a charged particle optical system configured to direct the beam of primary charged particles at a sample surface to inspect the sample surface;
a charged particle detector configured to detect charged particles returned from the sample surface,
wherein the charged particle detector comprises a first sensing element, a second sensing element, and a third sensing element;
a first pickup switch that is configured to be enabled between a first sensing element and a first node of an upper hierarchy of the switch matrix to allow charge to flow between the first sensing element and the first node via the first pickup switch, the first sensing element configured to receive charged particles of a first beam spot;
a first inter-element switch that is configured to be enabled between a second sensing element and a third sensing element to allow charge to flow between the second sensing element and the third sensing element via the first inter-element switch, the second sensing element and the third sensing element configured to receive charged particles of a second beam spot;
a second pickup switch that is configured to be disabled between the second sensing element and the first node to prevent charge from flowing between the second sensing element and the first node via the pickup switch; and
a third pickup switch that is configured to be enabled between the third sensing element and a second node of the upper hierarchy of the switch matrix to allow charge to flow between the third sensing element and the second node via the third pickup switch.
85. The charged particle beam apparatus of clause 84, wherein:
the first node is a common node of the upper hierarchy in a first section of sensing elements, the first section comprising the first sensing element and the second sensing element; and
the second node is a common node of the upper hierarchy in a second section of sensing elements, the second section comprising the third sensing element.
86. The charged particle beam apparatus of clause 85, further comprising:
a first interconnection switch that is configured to be disabled between the first node and the second node to prevent charge from flowing in the upper hierarchy between the first node and the second node via the first interconnection switch.
87. The charged particle beam apparatus of clause 84, further comprising:
a second inter-element switch that is configured to be disabled between a fourth sensing element and at least one of the first sensing element and the second sensing element to prevent charge from flowing between the fourth sensing element and at least one of the first sensing element and the second sensing element; and
a fourth pickup switch that is configured to be disabled between the fourth sensing element and the first node to prevent charge from flowing between the fourth sensing element and the first node via the fourth pickup switch.
88. The charged particle beam apparatus of clause 84, further comprising:
a first readout switch that is configured to be enabled between the upper hierarchy and first signal processing circuitry to allow a first signal to reach the first signal processing circuitry, the first signal representing at least the charge from the first sensing element; and
a second readout switch that is configured to be enabled between the upper hierarchy and second signal processing circuitry to allow a second signal to reach the second signal processing circuitry, the second signal representing at least the charge from the second sensing element.
89. The charged particle beam apparatus of clause 88, wherein one of the first signal processing circuitry and the second signal processing circuitry comprises and analog-to-digital converter (ADC).
90. The charged particle beam apparatus of clause 88, wherein the charged particle beam apparatus is configured to:
determine a first characteristic of the first beam spot based on the first signal; and
determine a second characteristic of the second beam spot based on the second signal.
91. The charged particle beam apparatus of clause 90, wherein:
the first characteristic comprises an intensity of the first beam spot; and
the second characteristic comprises an intensity of the second beam spot.

A non-transitory computer-readable medium may be provided that stores instructions for a processor of a controller (e.g., controller 109 in FIG. 1 or controller 804 in FIG. 8) for detecting a charged-particle beam according to the systems and processes disclosed above, consistent with embodiments in the present disclosure. For example, the instructions stored in the non-transitory computer-readable medium may be executed by the circuitry of the controller for performing method 1200 of FIG. 12 in part or in entirety. Alternatively, the instructions stored in the non-transitory computer-readable medium may be executed by the circuitry of the controller for performing any of the processes disclosed herein. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A charged particle beam apparatus, comprising:
a charged particle beam source configured to generate a beam of primary charged particles;
a charged particle optical system configured to direct the beam of primary charged particles at a sample surface to inspect the sample surface;
a charged particle detector configured to detect charged particles returned from the sample surface, wherein the charged particle detector comprises a first sensing element and a second sensing element; and
a controller comprising one or more processors and configured to cause the charged particle beam apparatus to perform a method comprising:
disabling a first inter-element switch between the first sensing element and the second sensing element to prevent charge from flowing between the first sensing element and the second sensing element via the first inter-element switch, the first inter-element switch forming part of a lower hierarchy of a switch matrix;
enabling a first pickup switch between the first sensing element and an upper hierarchy of the switch matrix to allow charge to flow between the first sensing element and the upper hierarchy via the first pickup switch; and
enabling a second pickup switch between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.

2. The charged particle beam apparatus of claim 1, wherein:
the charged particle detector comprises a plurality of sensing elements including the first sensing element and the second sensing element;
the plurality of sensing elements is divided into a plurality of sections of sensing elements by an interconnection switch between each section of sensing elements; and
each interconnection switch of the plurality of interconnection switches forms part of the upper hierarchy.

3. The charged particle beam apparatus of claim 2, wherein:
the first sensing element forms part of a first section of the plurality of sections;
the second sensing element forms part of a second section of the plurality of sections; and
the first sensing element and the second sensing element are coupled to a common analog signal path of the detector at the upper hierarchy by enabling a first interconnection switch between the first section and the second section.

4. The charged particle beam apparatus of claim 3, wherein:
the upper hierarchy comprises a readout switch coupled to signal processing circuitry of the charged particle detector.

5. The charged particle beam apparatus of claim 4, wherein:
the first interconnection switch is located between the first pickup switch and the readout switch on the common analog signal path;
the first interconnection switch is not located between the second pickup switch and the readout switch on the common analog signal path.

6. The charged particle beam apparatus of claim 2, wherein:
the first sensing element and the second sensing element form part of a first section of the plurality of sections;
the first sensing element is coupled to the common analog signal path of the detector at a first node of the upper hierarchy by the first pickup switch; and
the second sensing element is coupled to the common analog signal path of the detector at the first node of the upper hierarchy by the second pickup switch.

7. The charged particle beam apparatus of claim 6, wherein the controller is further configured to cause the charged particle beam apparatus to perform:
enabling a second inter-element switch between the second sensing element and a third sensing element of the charged particle detector to allow charge to flow between the third sensing element and the second sensing element via the second inter-element switch, the second inter-element switch forming part of the lower hierarchy; wherein:
the third sensing element forms part of a second section of the plurality of sections.

8. The charged particle beam apparatus of claim 7, wherein the controller is further configured to cause the charged particle beam apparatus to perform:
disabling a third pickup switch between the third sensing element and a second node of the upper hierarchy to prevent charge from flowing between the third sensing element and the second node via the third pickup switch.

9. The charged particle beam apparatus of claim +6, wherein the controller is further configured to cause the charged particle beam apparatus to perform:
disabling a third pickup switch between a third sensing element and the first node to prevent charge from flowing between the third sensing element and the first node via the third pickup switch; and
enabling a ground switch between the third sensing element and a ground connection to prevent charge from accumulating at the third sensing element,
wherein the third sensing element forms part of the first section of the plurality of sections.

10. The charged particle beam apparatus of claim 1, wherein the first sensing element and the second sensing element comprise PIN diodes.

11. The charged particle beam apparatus of claim 1, wherein the charged particle detector is part of a charged particle beam system.

12. The charged particle beam apparatus of claim 11, wherein the charged particle beam system is a SEM inspection tool.

13. The charged particle beam apparatus of claim 1, wherein the controller is further configured to cause the charged particle beam apparatus to perform:
determining a size, shape or location of a beam spot on a surface of the charged particle detector;
assigning the first sensing element and the second sensing element to the common analog signal path based on the determined size, shape or location of the beam spot; and
selecting a switching configuration based on the assignment;
wherein the switching configuration comprises the disabled first inter-element switch, the enabled first pickup switch, and the enabled second pickup switch.

14. The charged particle beam apparatus of claim 13, wherein the switching configuration is selected based on a parasitic parameter of the switching configuration.

15. A non-transitory computer-readable medium that stores a set of instructions that is executable by at least one processor of an apparatus to cause the apparatus to perform a method for configuring a switch matrix in a charged particle detector, the method comprising:
disabling a first inter-element switch between a first sensing element and a second sensing element of the charged particle detector to prevent charge from flowing between the first sensing element and the second sensing element via the first inter-element switch, the first inter-element switch forming part of a lower hierarchy of a switch matrix;
enabling a first pickup switch between the first sensing element and an upper hierarchy of the switch matrix to allow charge to flow between the first sensing element and the upper hierarchy via the first pickup switch; and
enabling a second pickup switch between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.

16. The non-transitory computer-readable medium of claim 15, wherein:
the charged particle detector comprises a plurality of sensing elements including the first sensing element and the second sensing element;
the plurality of sensing elements is divided into a plurality of sections of sensing elements by an interconnection switch between each section of sensing elements; and
each interconnection switch of the plurality of interconnection switches forms part of the upper hierarchy.

17. The non-transitory computer-readable medium of claim 16, wherein:
the first sensing element forms part of a first section of the plurality of sections; and
the second sensing element forms part of a second section of the plurality of sections;
wherein the set of instructions that is executable by the at least one processor of the apparatus causes the apparatus to further perform
enabling a first interconnection switch between the first section and the second section to couple the first sensing element and the second sensing element to a common analog signal path of the detector at the upper hierarchy.

18. The non-transitory computer-readable medium of claim 16, wherein:
the first sensing element and the second sensing element form part of a first section of the plurality of sections;
the first sensing element is coupled to the common analog signal path of the detector at a first node of the upper hierarchy by the first pickup switch; and
the second sensing element is coupled to the common analog signal path of the detector at the first node by the second pickup switch.

19. The non-transitory computer-readable medium of claim 15, wherein the set of instructions that is executable by the at least one processor of the apparatus causes the apparatus to further perform:
determining a size, shape or location of a beam spot on a surface of the charged particle detector;
assigning the first sensing element and the second sensing element to the common analog signal path based on the determined size, shape or location of the beam spot; and
selecting a switching configuration based on the assignment;
wherein the switching configuration comprises the disabled first inter-element switch, the enabled first pickup switch, and the enabled second pickup switch.

20. A method of configuring a switch matrix in a charged particle detector, comprising:
disabling a first inter-element switch between a first sensing element and a second sensing element of the charged particle detector to prevent charge from flowing between the first sensing element and the second sensing element via the first inter-element switch, the first inter-element switch forming part of a lower hierarchy of the switch matrix;
enabling a first pickup switch between the first sensing element and an upper hierarchy of the switch matrix to allow charge to flow between the first sensing element and the upper hierarchy via the first pickup switch; and
enabling a second pickup switch between the second sensing element and the upper hierarchy to allow charge to flow between the second sensing element and the upper hierarchy via the second pickup switch;
wherein the first sensing element and the second sensing element are coupled to a common analog signal path of the detector at the upper hierarchy.
